(19) United States
(12) Patent Application Publication
(10) Pub. No.: US 2003/0123385 A1
(43) Pub. Date: Jul. 3, 2003

(54) Unified digital subscriber line self-installation process and kit

(76) Inventor: Philip Ted Kortum, Austin, TX (US)

Correspondence Address: BRINKS HOFER GILSON & LIONE, P.O. BOX 10395, CHICAGO, IL, 60611, US

(21) Appl. No.: 09/847,045

(22) Filed: May 1, 2001

(51) Int. Cl. G06F 17/60; H04J 1/16; H04L 1/00; H04J 3/14; G06F 11/00; H04L 12/26; G08C 15/00; G01R 31/08

(52) U.S. Cl. 370/222; 379/90.01; 379/93.01

(57) ABSTRACT

A digital subscriber line self-installation kit comprises an optional network card, a digital subscriber line modem, at least one digital subscriber line filter, a computer-readable medium whose contents comprise computer-readable connection software code, and an instruction manual. The instruction manual describes a unified installation process for the network card, the digital subscriber line modem, the at least one digital subscriber line filter, and the computer-readable connection software code, wherein the unified installation process requires at most one operating system selection step by a user.

### NOTICE OF COPYRIGHT

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

The present invention relates to Digital Subscriber Line installation.

### BACKGROUND OF THE INVENTION

Digital Subscriber Line (DSL) is a high speed internet access technology. Unlike other high-speed internet access technologies, DSL runs over ordinary telephone lines. By its nature, DSL is amenable to customer self-installation.

DSL requires the installation of up to five components: a network card, a DSL modem, DSL filters, connection software, and Internet Service Provider (ISP) specific software. Current DSL self-installation kits comprise a collection of each of these vendor products packaged into a single box. These kits present customers with as many as five different instruction sets, many of which being labeled “Read Me First”. As shown in FIG. 1, the kit may comprise a network card vendor installation manual 100, a filter vendor installation manual 102, a modem vendor installation manual 104, a connection software vendor installation manual 106, and an ISP vendor installation manual 110.

There are several shortcomings associated with the above-described self-installation kits. A user may be uncertain as to which manual to read first, and unable to identify key steps in each manual. User testing has shown that critical installation steps were often missed with the above-described self-installation kits. Consequently, users were required to redo portions of the installation due to an incorrect installation sequence.

Further, many vendor components are specific to a particular computer operating system (OS). Vendors include “universal” manuals which inter-mix instructions for different operating systems. For example, the network card vendor installation manual 100 may inter-mix instructions for N different operating systems (as indicated by reference numerals 112, 114 and 116). The modem vendor installation manual 102 may inter-mix instructions for N different operating systems (as indicated by reference numerals 120, 122 and 124). The connection software vendor installation manual 106 may inter-mix instructions for N different operating systems (as indicated by reference numerals 126, 130 and 132). Users are required to make the correct OS selection in each manual, and then find the appropriate OS instruction subset in each manual. Testing has shown that the wrong OS instruction subset is followed by an undesirably high proportion of users.

Still further, the ISP component is typically shipped separately from the rest of the DSL kit. This also results in customer confusion and installation sequencing errors. Yet still further, conflicting information may be present in different manuals since the vendors typically construct their manuals in isolation from each other.

All of the aforementioned shortcomings have led to an undesirably high rate of failures and frustration for customers who attempt to self-install DSL. These failures lead to help desk calls and, in certain cases, the dispatch of a technician to the customer's premise.

### BRIEF DESCRIPTION OF THE DRAWINGS

The invention is pointed out with particularity in the appended claims. However, other features of the invention will become more apparent and the invention will be best understood by referring to the following detailed description in conjunction with the accompanying drawings in which:

FIG. 1 is a flow diagram of a prior art self-installation process for a digital subscriber line;

FIG. 2 is a flow diagram of an embodiment of a digital subscriber line self-installation process in accordance with the present invention;

FIG. 3 is a block diagram of an embodiment of a digital subscriber line self-installation kit;

FIGS. 4 to 29 illustrate an embodiment of a unified installation manual for a first class of operating systems; and

FIGS. 30 to 57 illustrate an embodiment of a unified installation manual for a second class of operating systems.

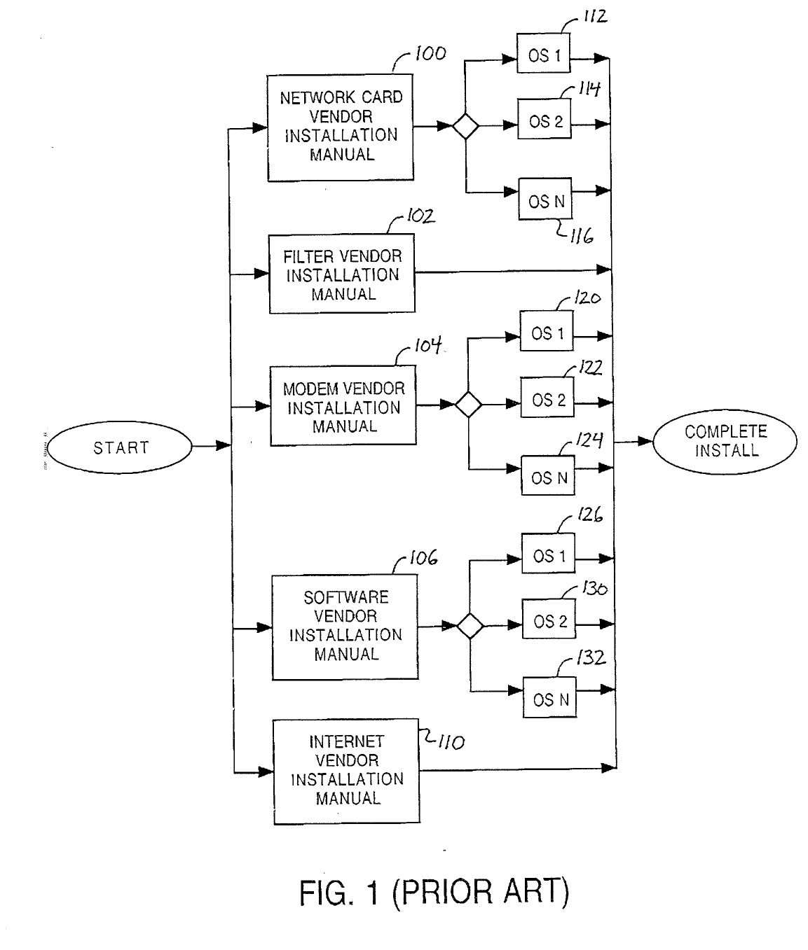

### DETAILED DESCRIPTION OF PREFERRED EMBODIMENTS

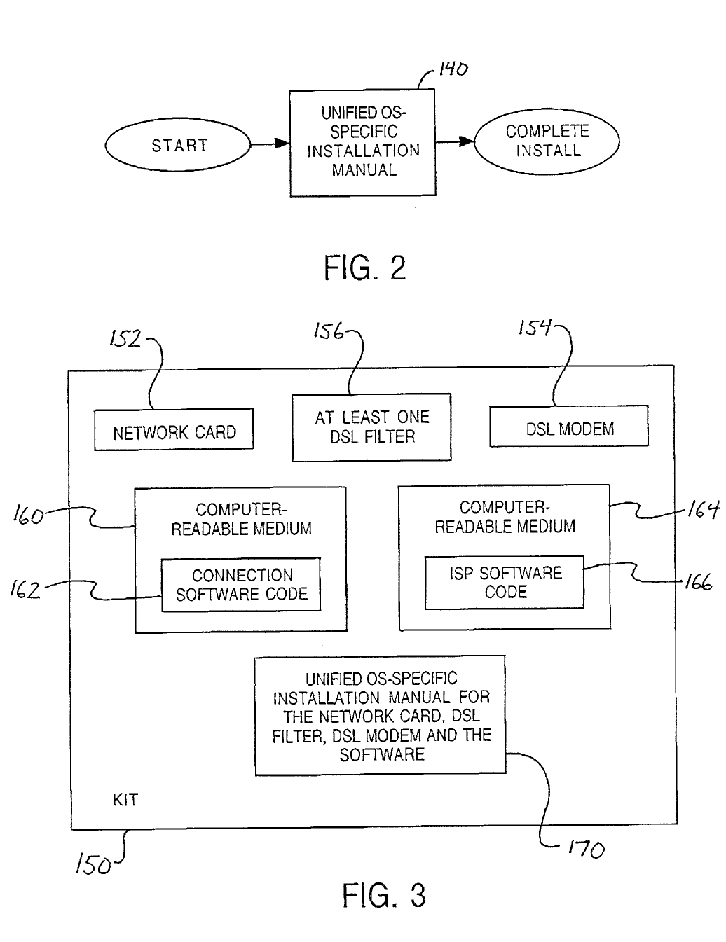

Briefly, embodiments of the present invention provide an improved process and kit for DSL self-installation wherein an entire installation process is described within a single instruction manual 140, as shown in FIG. 2. Beneficially, the installation process requires no more than one operating system selection step by a user.

FIG. 3 is a block diagram of an embodiment of a digital subscriber line self-installation kit 150. The kit 150 comprises an optional network card 152, a digital subscriber line modem 154, at least one digital subscriber line filter 156, a computer-readable medium 160 whose contents comprise computer-readable connection software code 162, an optional computer-readable medium 164 whose contents comprise computer-readable ISP-specific software code 166, and an instruction manual 170. The network card 152, the digital subscriber line modem 154, the at least one digital subscriber line filter 156, and the computer-readable media 160 and 164 may be contained within a container such as a box to form the kit 150.

The various hardware components of the kit 150 typically are provided by different vendors. Thus, each hardware component may be housed within its own container, such as a box, which includes an instruction manual from the vendor. The instruction manual 170 obviates the need for a user to refer to any of the vendor instruction manuals. In particular, the instruction manual 170 describes a unified installation process for the digital subscriber line modem 154, the at least one digital subscriber line filter 156, the computer-readable connection software code 162, and optionally for the network card 152 and the computer-readable ISP-specific software code 166. Further, the steps in the unified installation process are customized to reflect the set-up and configuration that are most desirable to customers of a DSL provider, rather than a generic instruction set designed for all possible contingencies.

Beneficially, the unified installation process requires no more than one operating system selection step by the user. Optionally, the user identifies his/her computer's operating system during the process of ordering DSL. In this case, the correct manual for the specific operating system/modem combination may be packaged in the self-installation kit 150 so that no operating system selection steps are required by the user upon receiving the kit 150. As another option, the kit 150 may comprise a plurality of instruction manuals (which includes the instruction manual 170), each being specific to a class of operating systems. In this case, the only operating system selection step to be performed by the user is selecting the correct one of the instruction manuals upon receiving the kit 150. Once the user begins to refer to the instruction manual 170, no further operating system selection steps are required. As a further option, the instruction manual 170 may include one section providing a unified installation process for a first operating system, and another section providing a unified installation process for a second operating system. In this case, the only operating system selection step to be performed by the user is selecting the correct section of the instruction manual 170. Once the user is within the correct section, no further operating system selection steps are required.

Optionally, the instruction manual 170 further provides point of contact telephone numbers for specific installation components and specific installation steps. For example, the instruction manual 170 may provide a first point of contact telephone number for help questions associated with the network card 152, a second point of contact telephone number for help questions associated with the digital subscriber line modem 154, a third point of contact telephone number for help questions associated with the at least one digital subscriber line filter 156, a fourth point of contact telephone number for help questions associated with the connection software code 162, and a fifth point of contact telephone number for help questions associated with the ISP-specific software code 166.

It is noted that the computer-readable media 160 and 164 may have various embodiments, including but not limited to optical media such as an optical disk, magnetic media such as a magnetic disk or magnetic tape, and electronic media such as an electronic memory card. Further, the computer-readable media 160 and 164 may be embodied either by two or more distinct members (e.g. two different disks), or by a single member (e.g. a single disk).

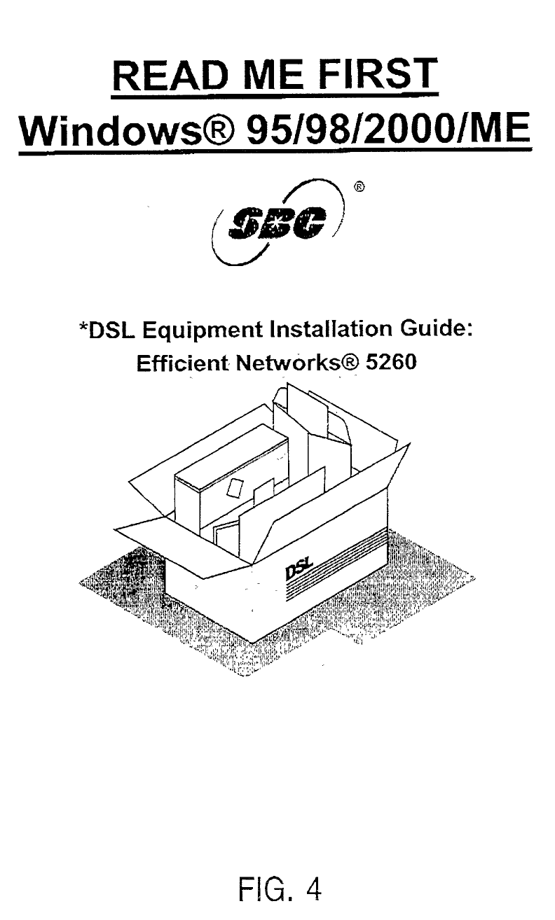

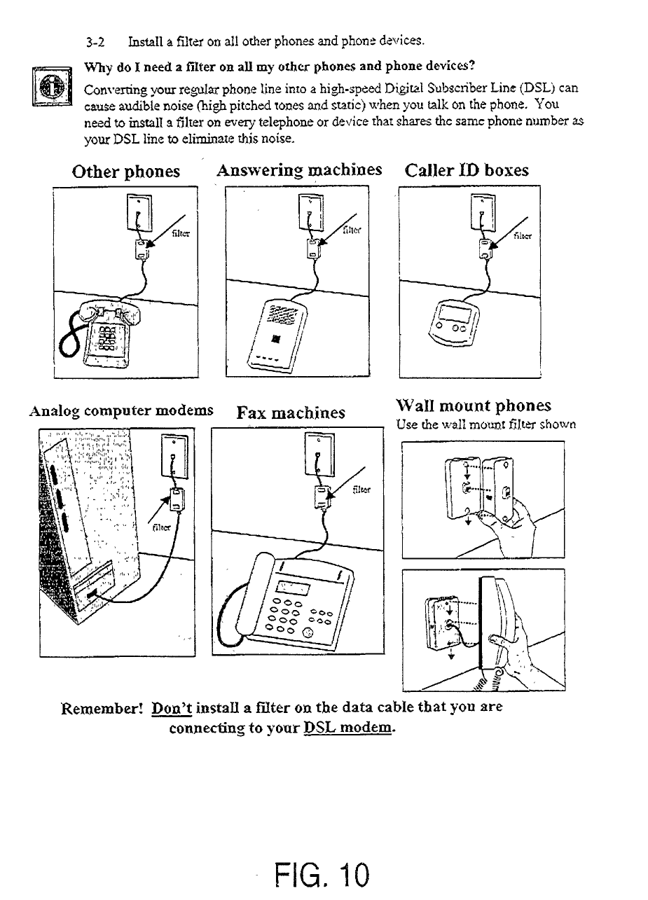

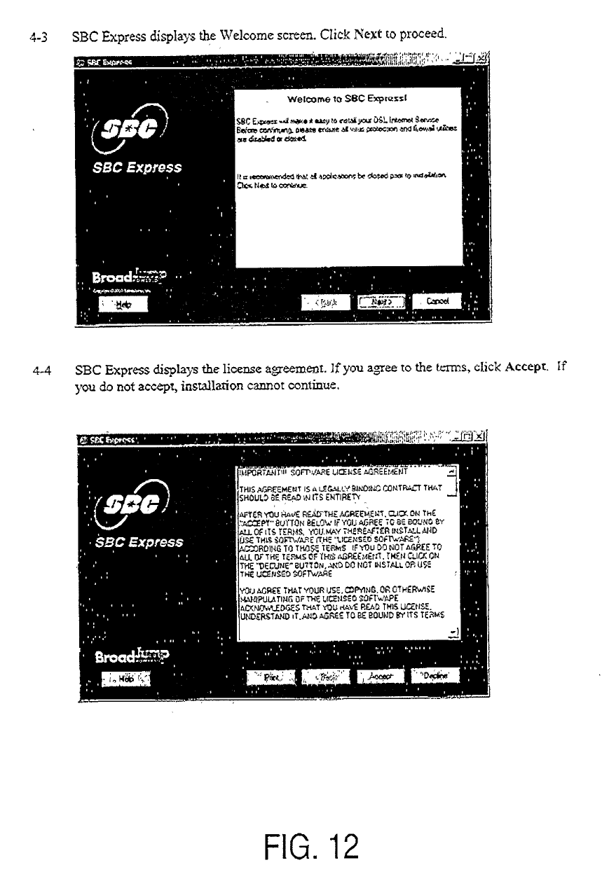

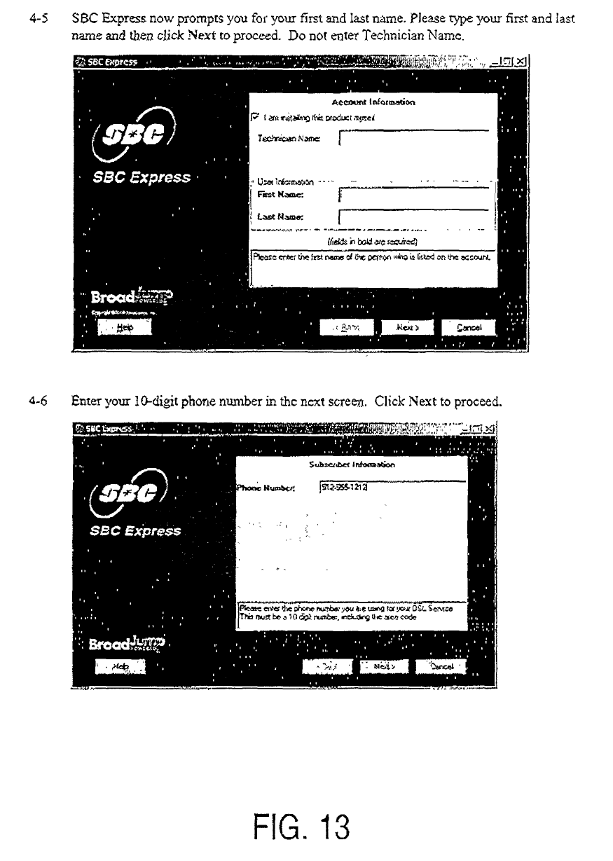

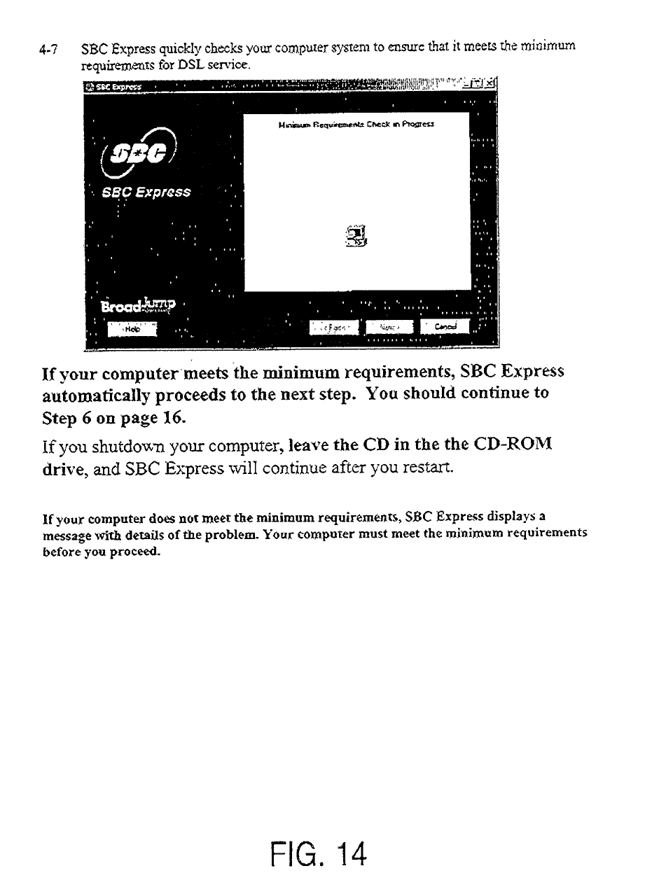

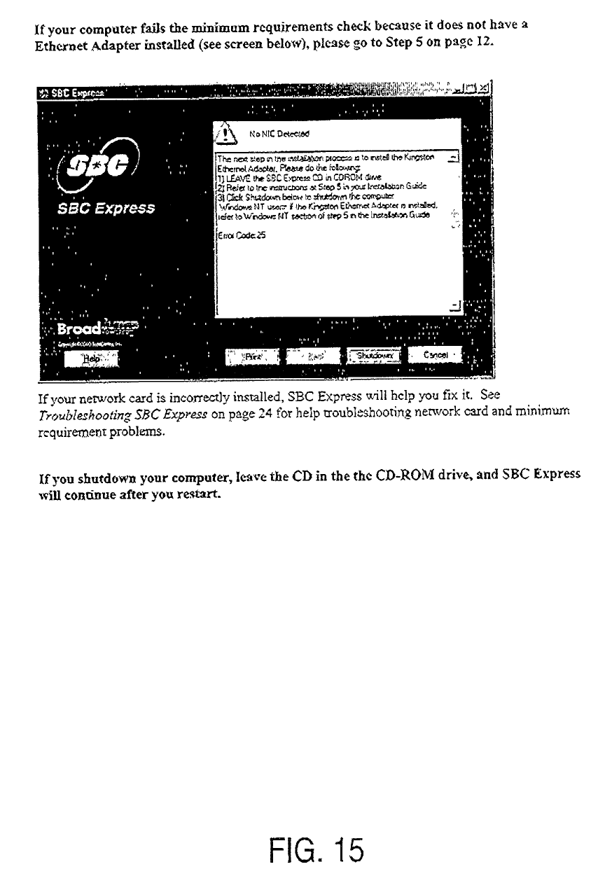

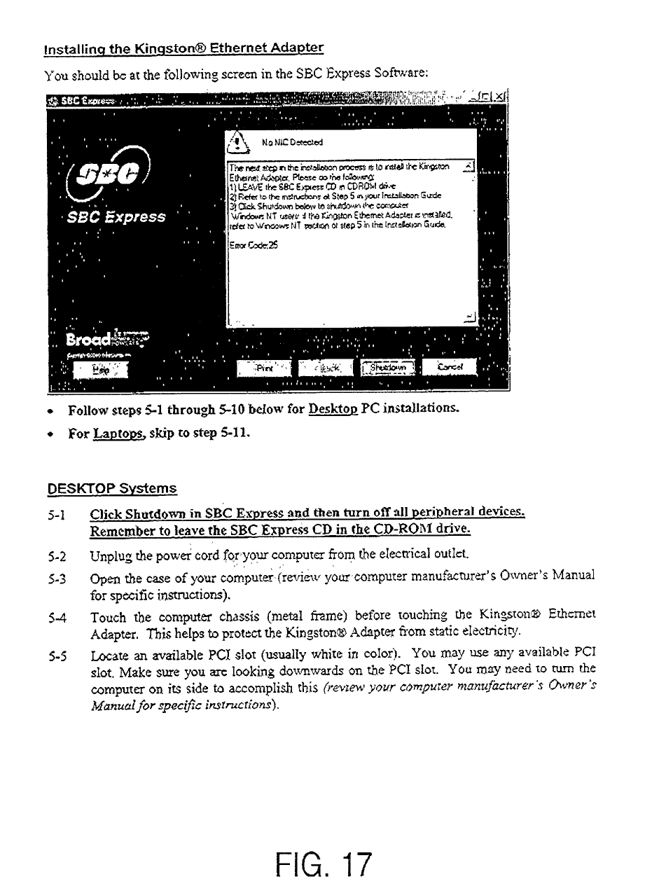

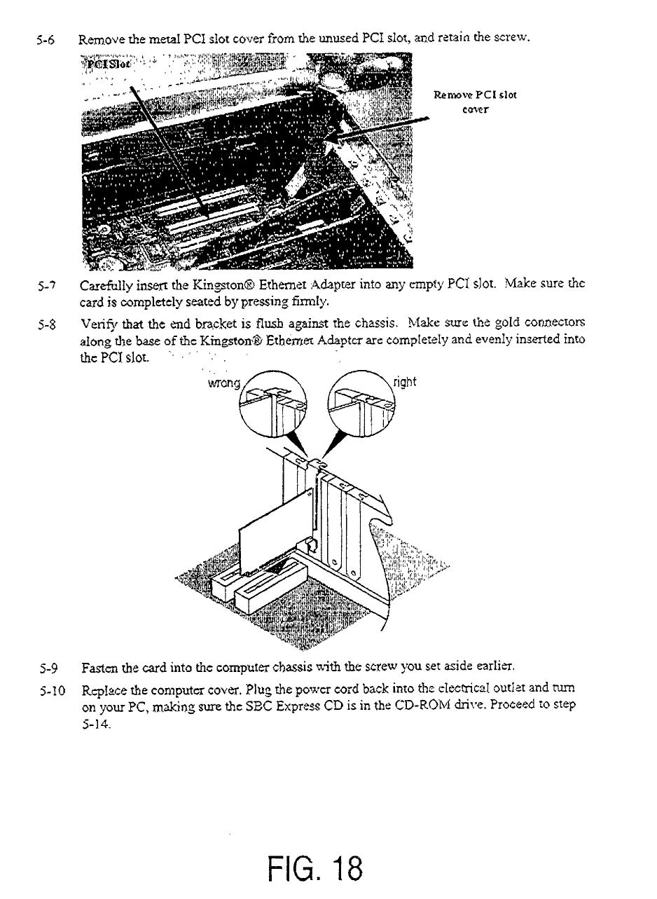

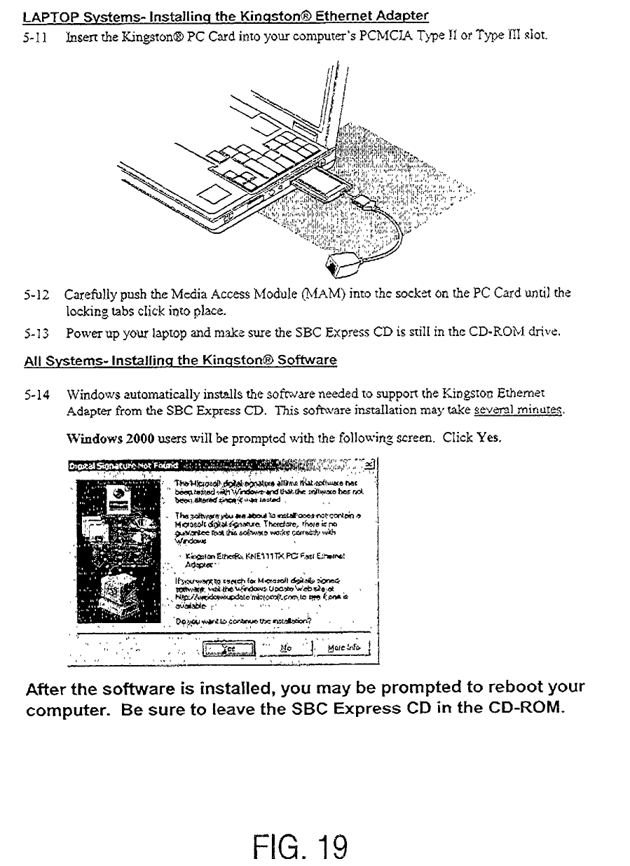

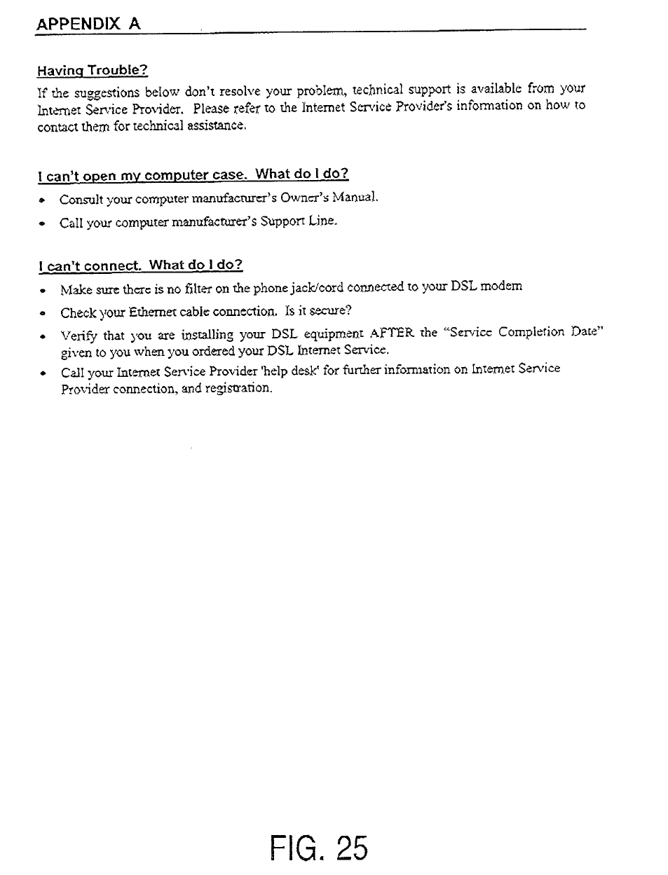

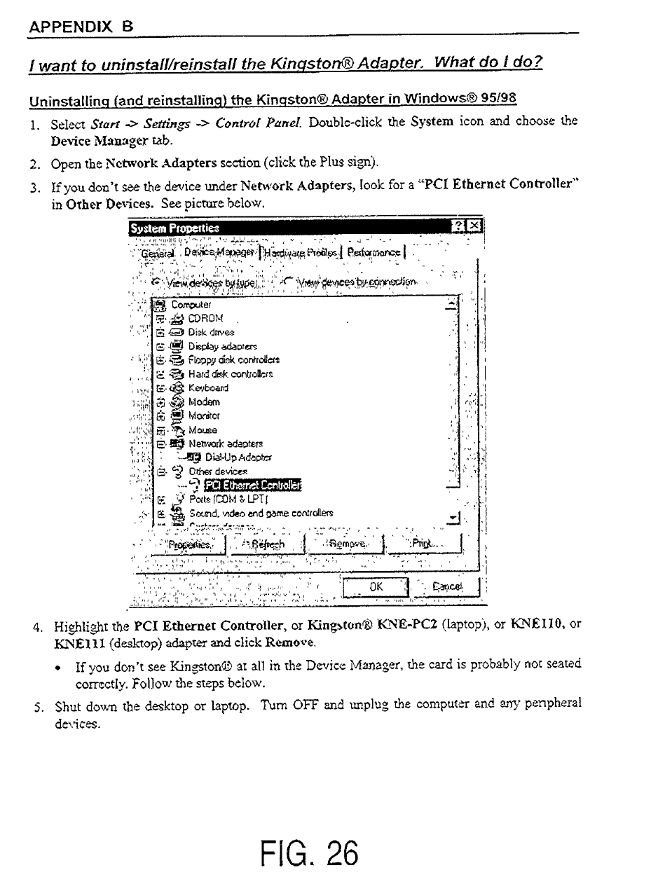

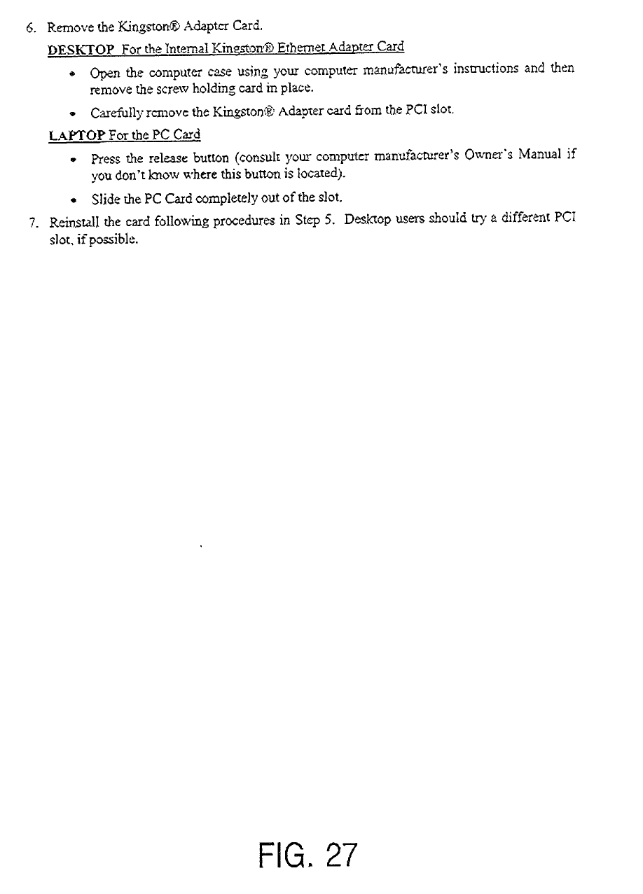

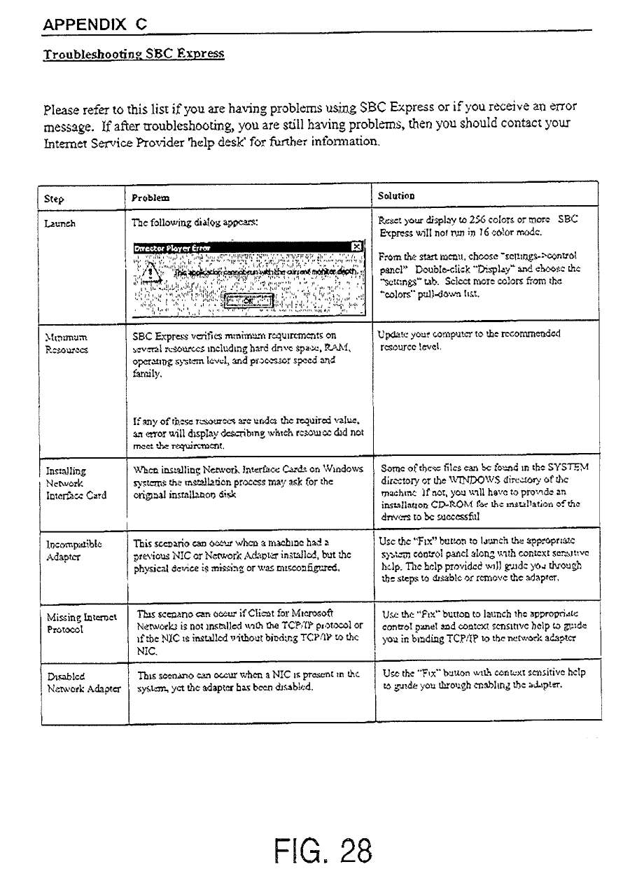

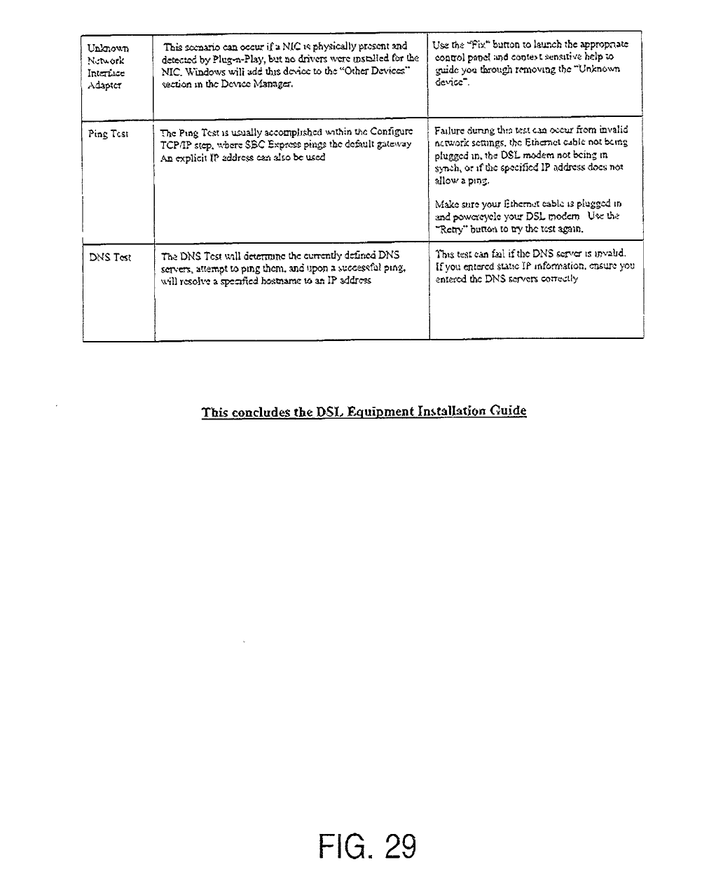

FIGS. 4 to 29 illustrate an embodiment of a unified installation manual for a first class of operating systems. The first class of operating systems consists of WINDOWS 95®, WINDOWS 98®, WINDOWS 2000® and WINDOWS ME® from Microsoft Corporation.

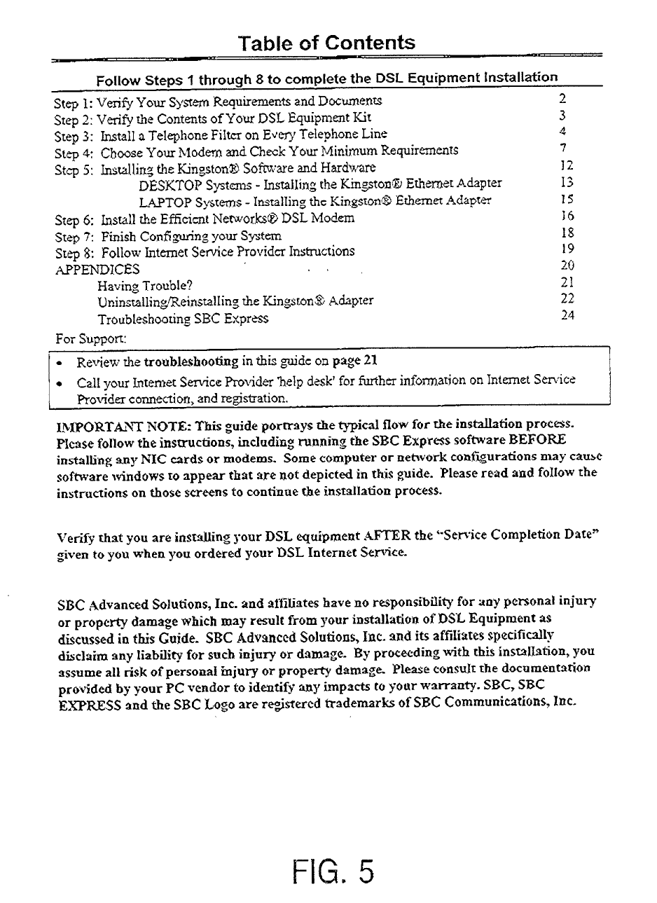

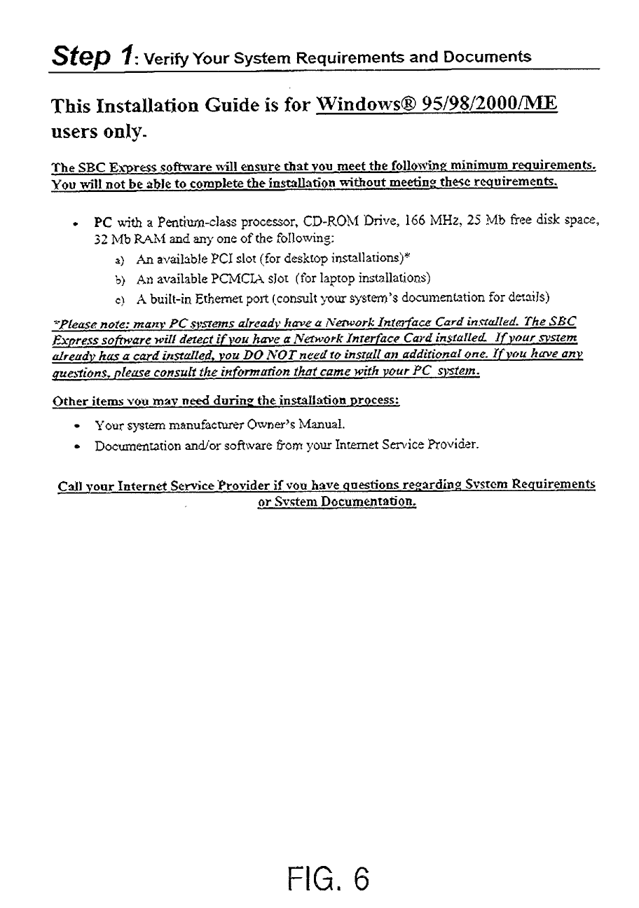

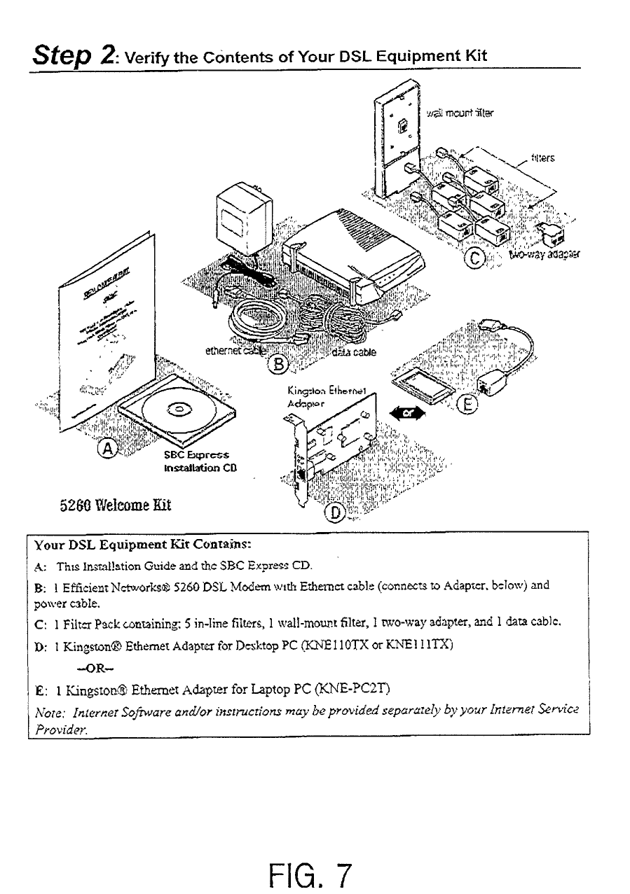

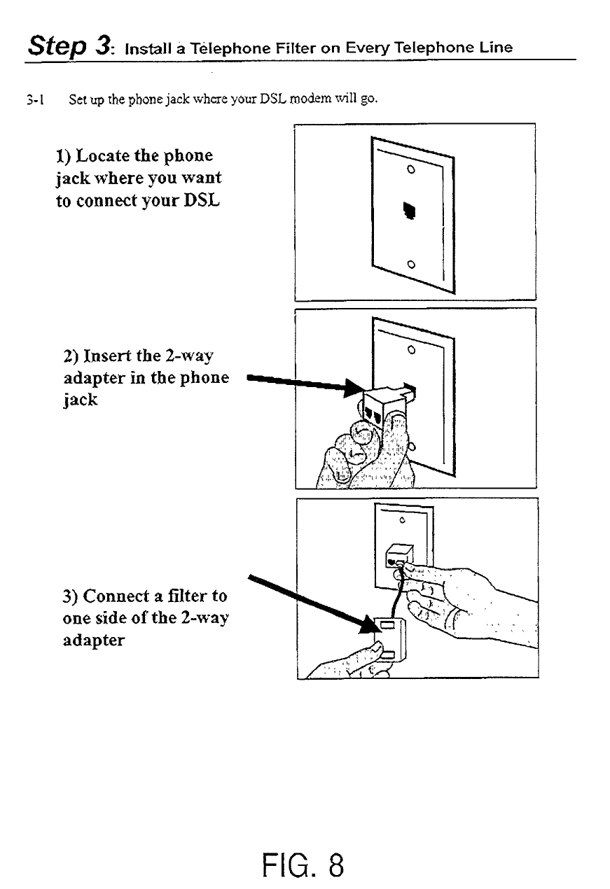

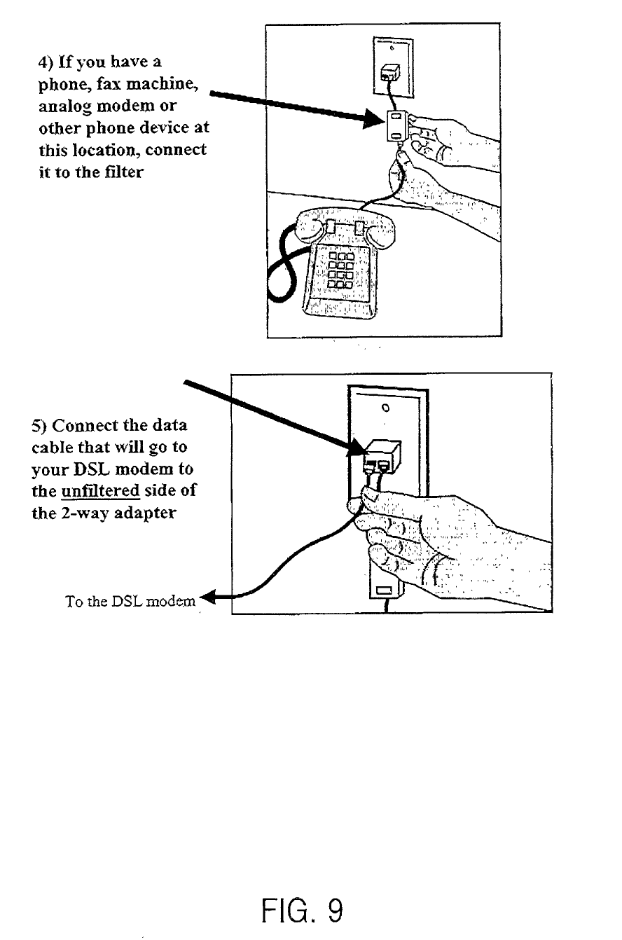

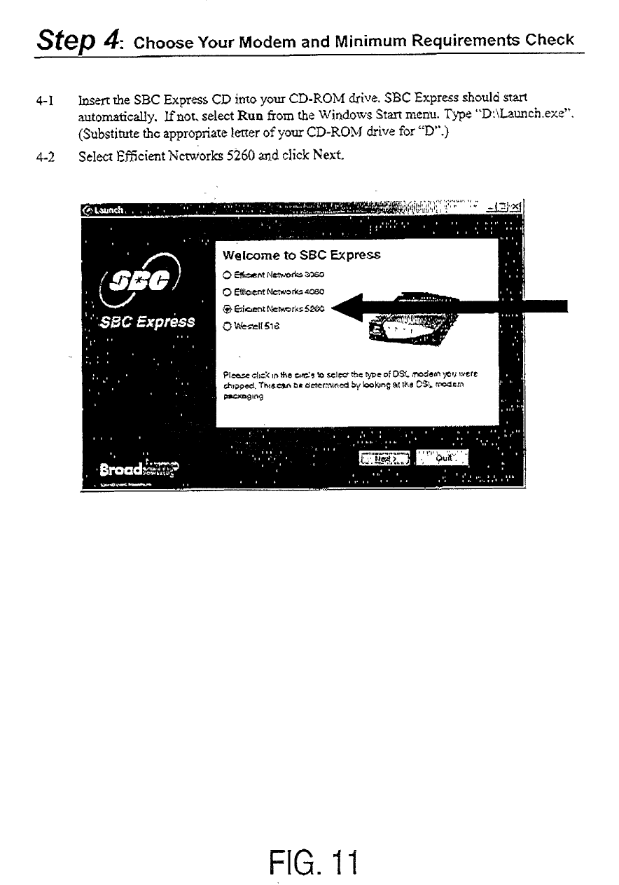

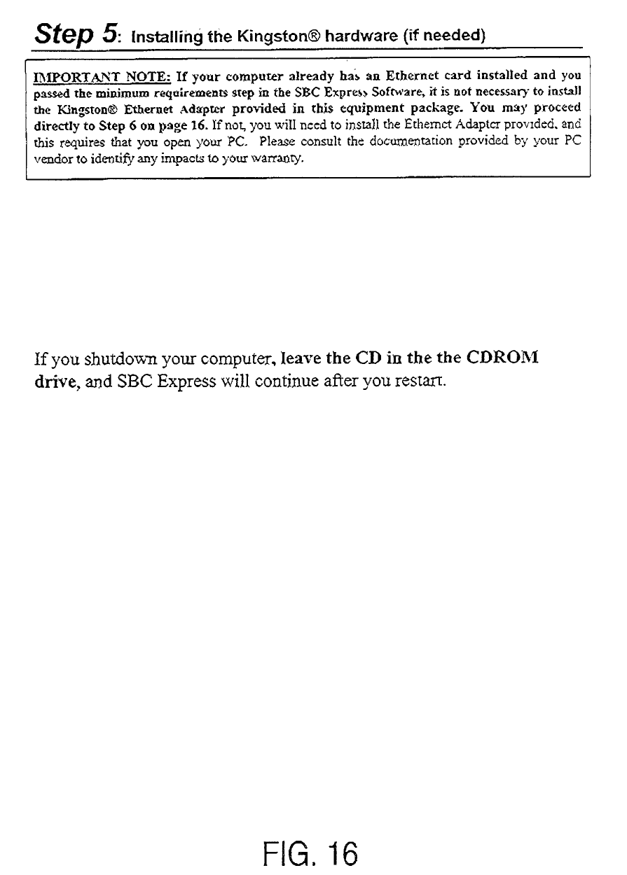

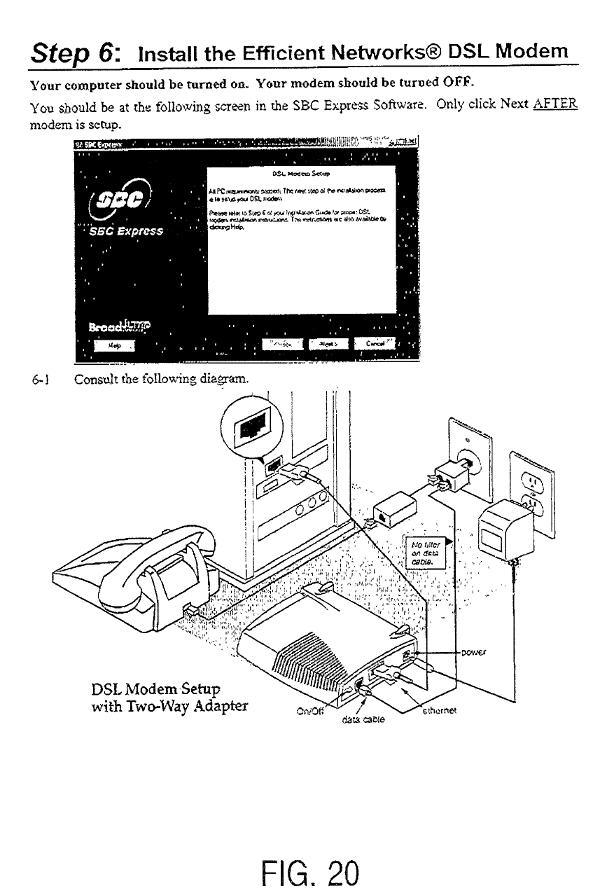

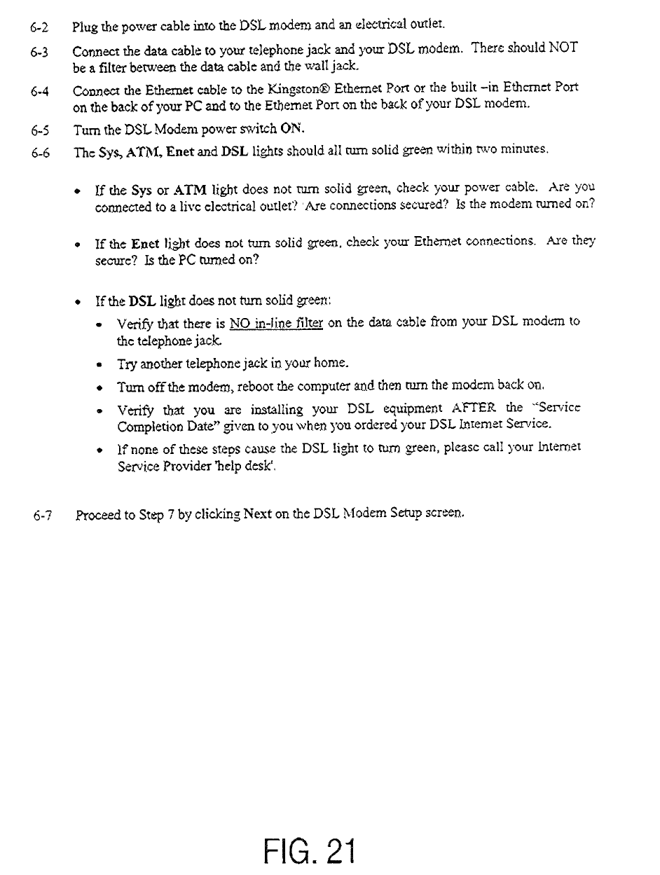

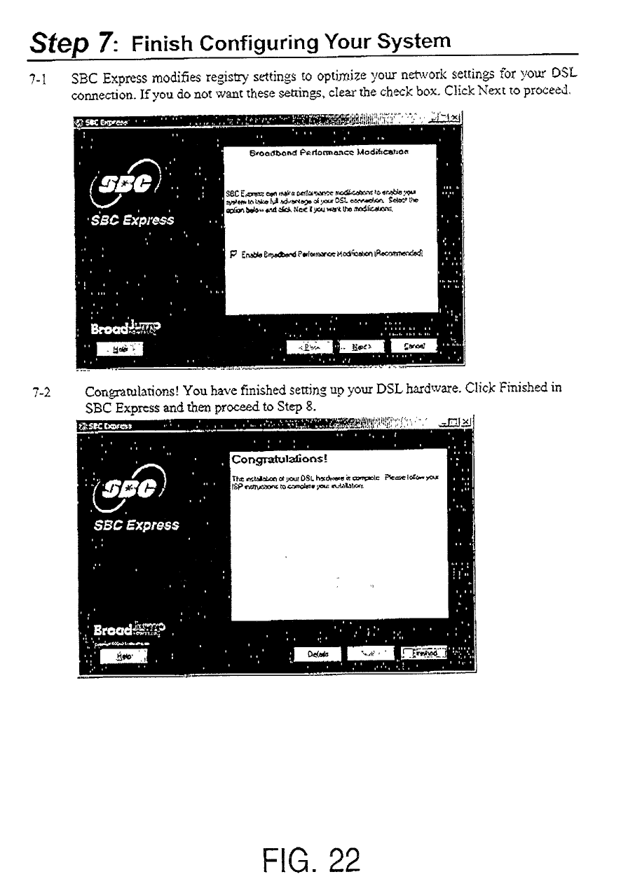

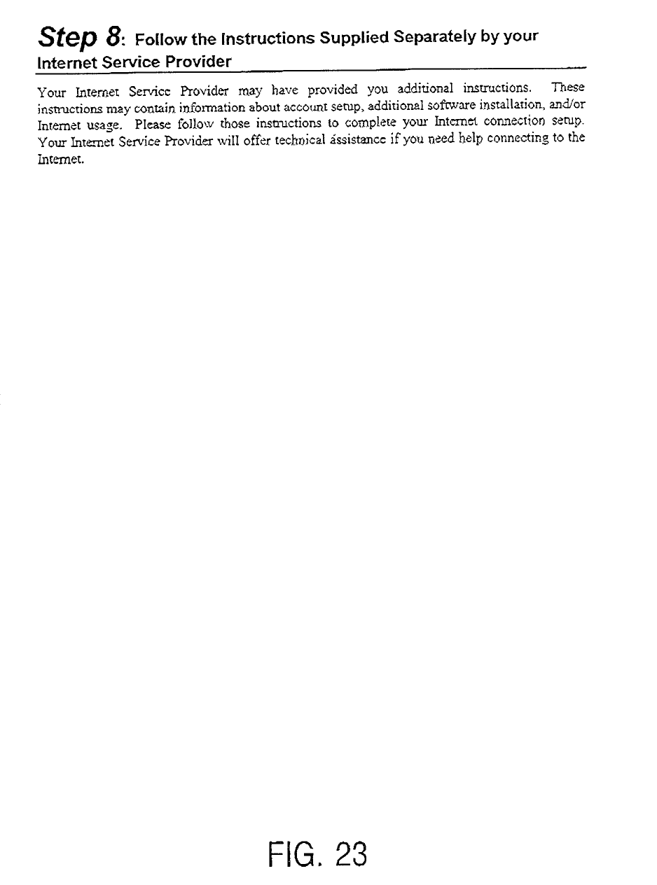

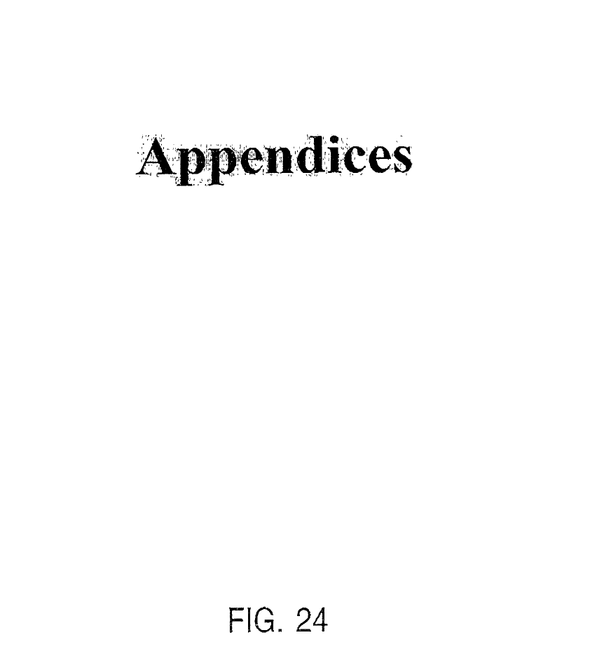

As shown in FIG. 4, the cover of the manual is clearly labeled “READ ME FIRST” and identifies the class of WINDOWS® operating systems. FIG. 5 shows a page of the manual which provides a Table of Contents. FIG. 6 shows a page of the manual which describes a step to verify the requirements to install the components in the user's computer. FIG. 7 shows a page of the manual which describes a step to verify the contents of the kit. FIGS. 8, 9 and 10 show pages of the manual which describe a step of installing a digital subscriber line filter on every telephone line. FIGS. 11 to 15 show pages of the manual which describe steps performed using connection software code. FIGS. 16 to 19 show pages of the manual which describe steps to install an Ethernet network card. FIGS. 20 and 21 show pages of the manual which describe steps to install a DSL modem. FIG. 22 shows a page of the manual which describes steps performed using the connection software code to finalize configuration of the system. FIG. 23 shows a page of the manual which directs the user to install ISP-specific software code. FIGS. 24 to 29 provide appendices to supplement the installation process.

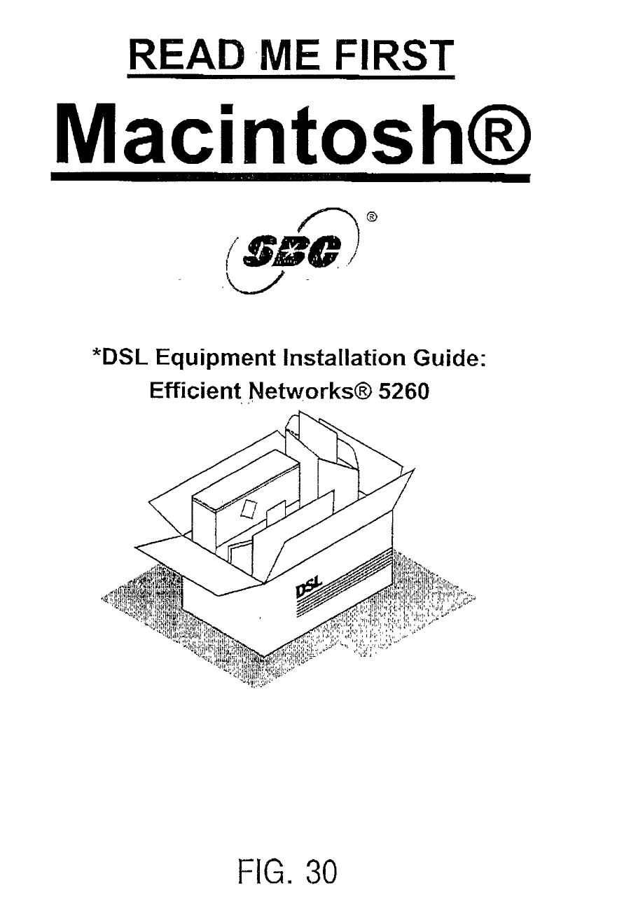

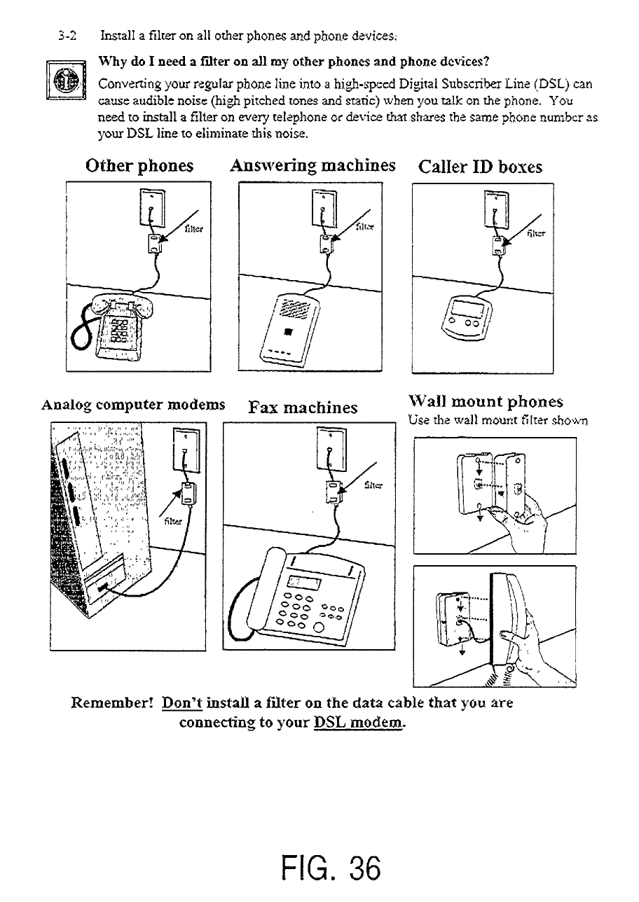

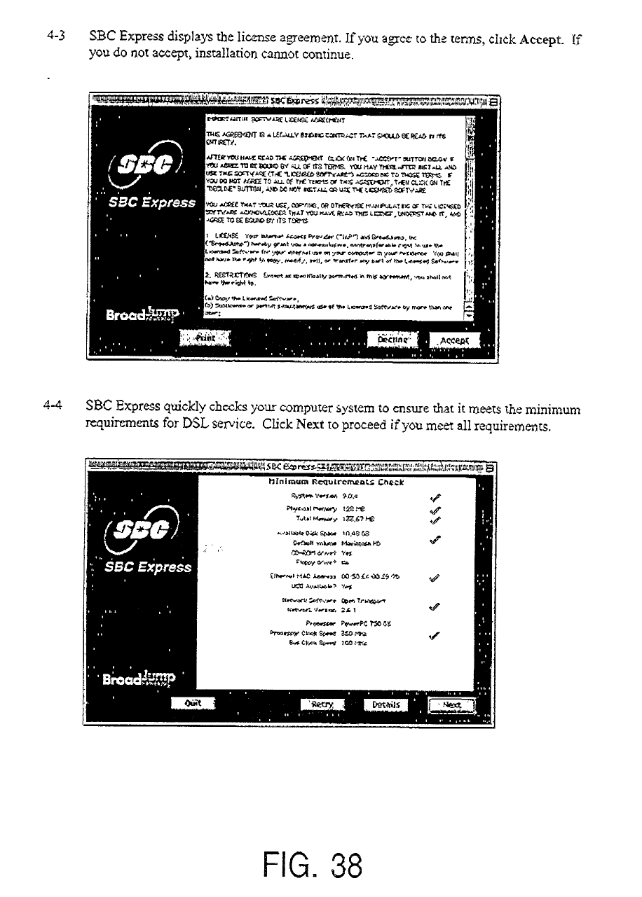

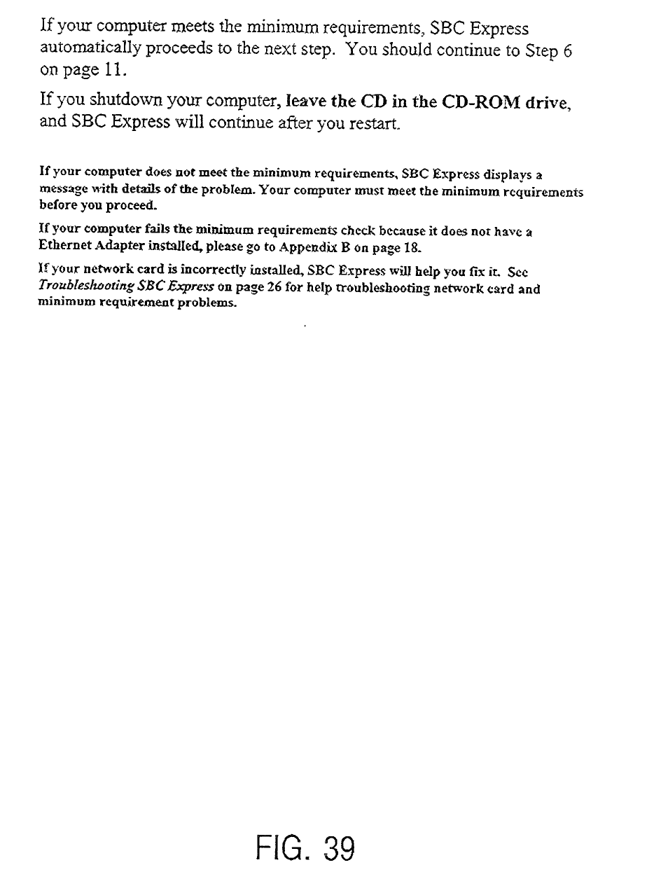

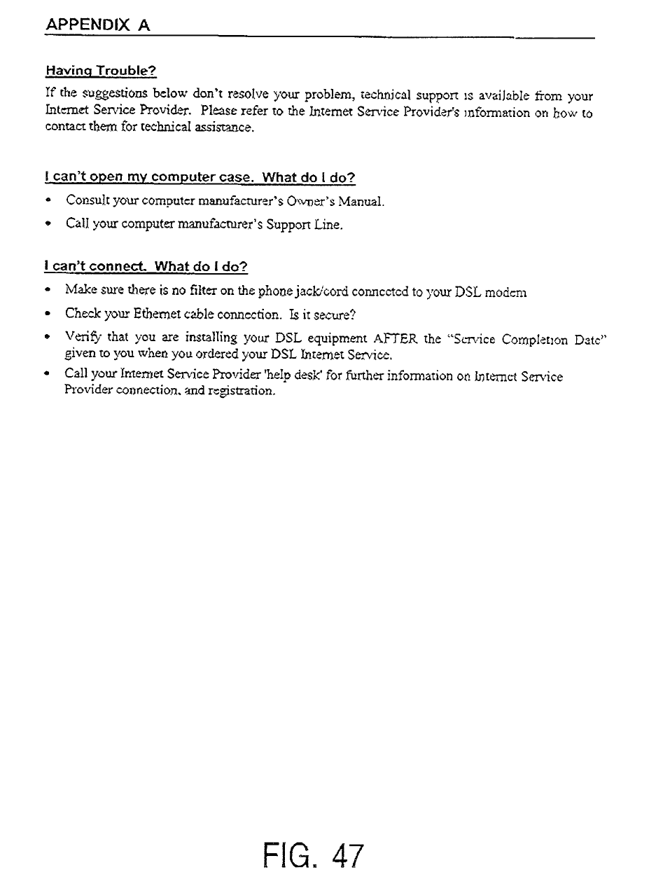

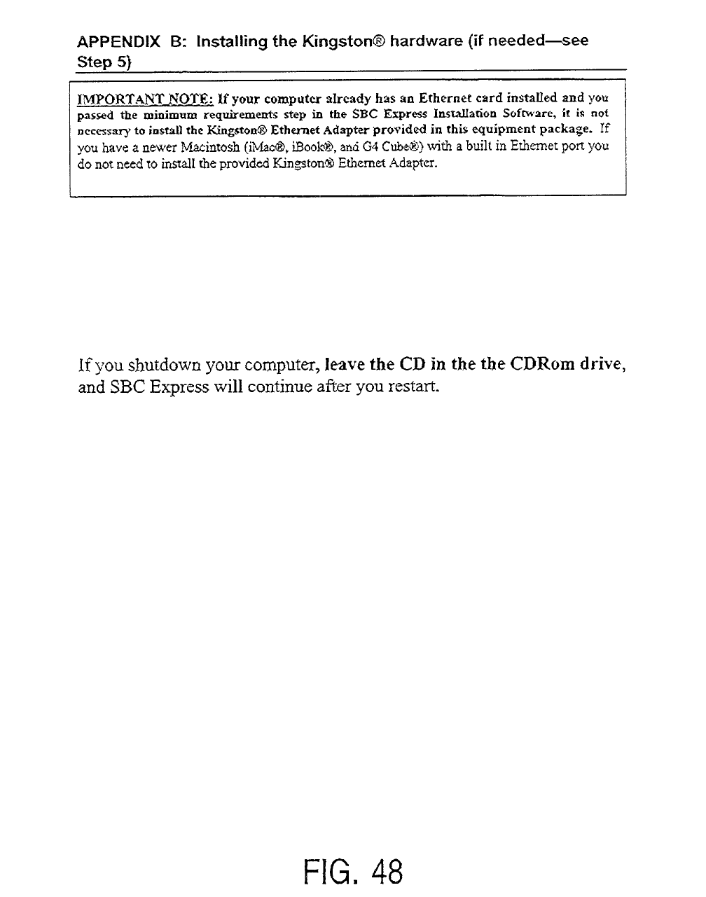

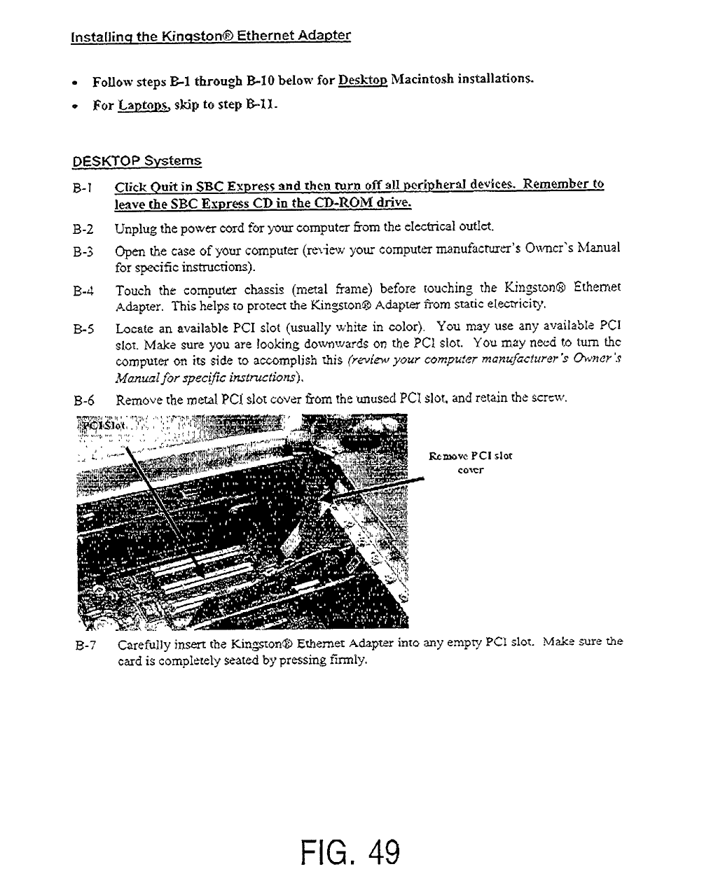

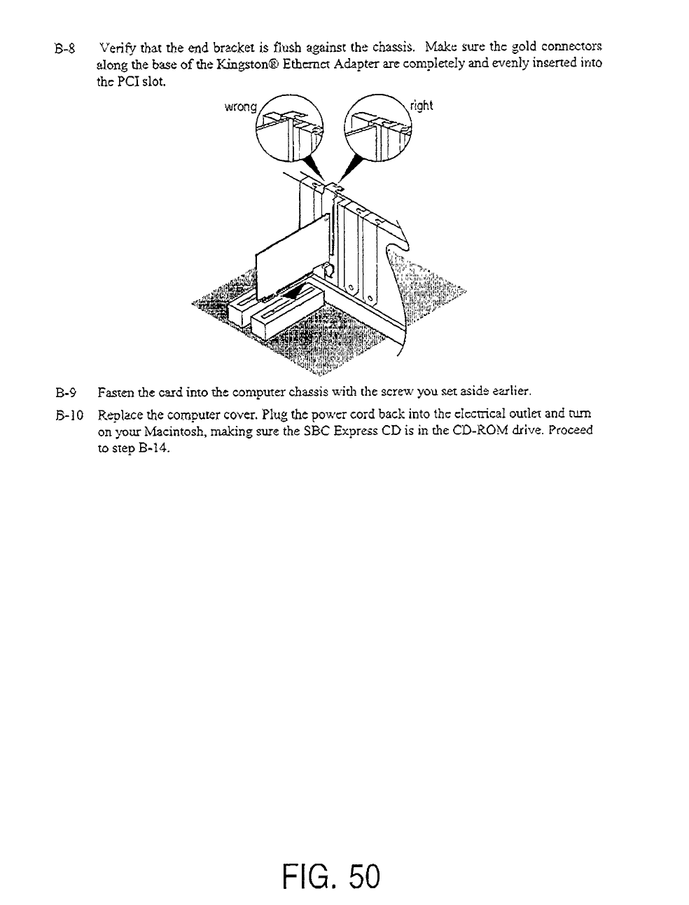

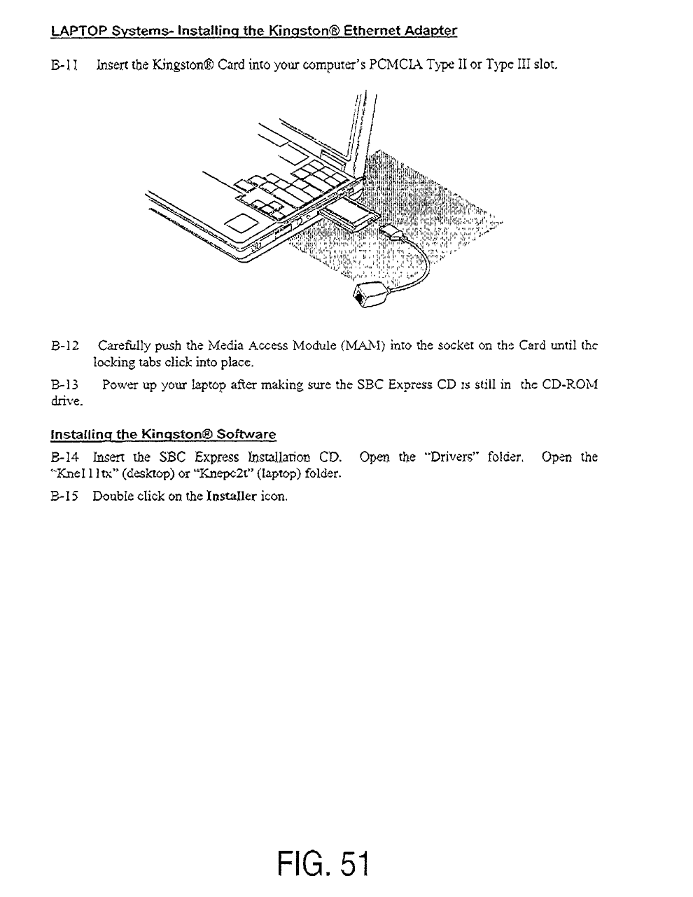

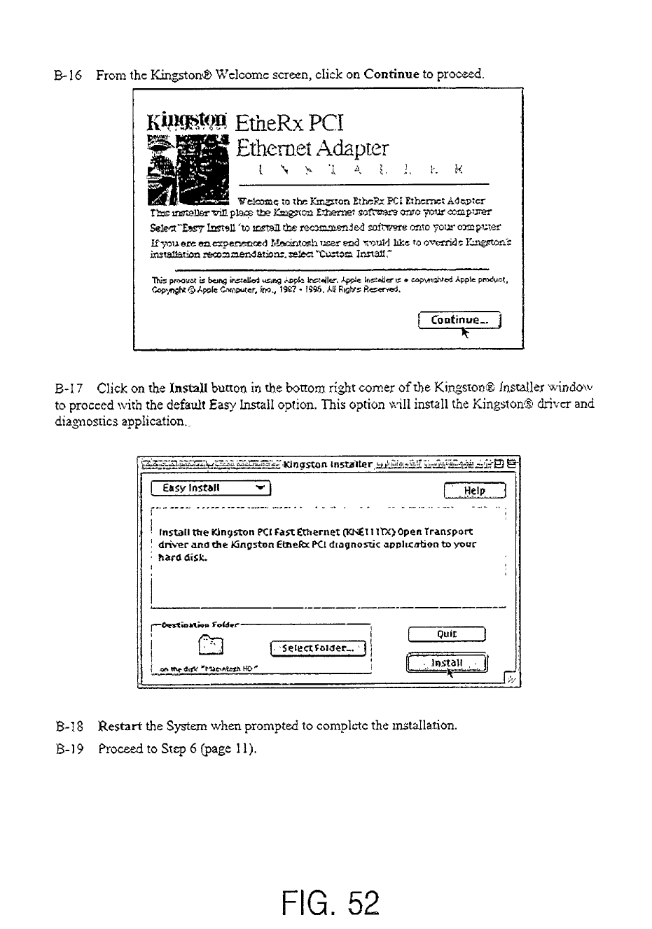

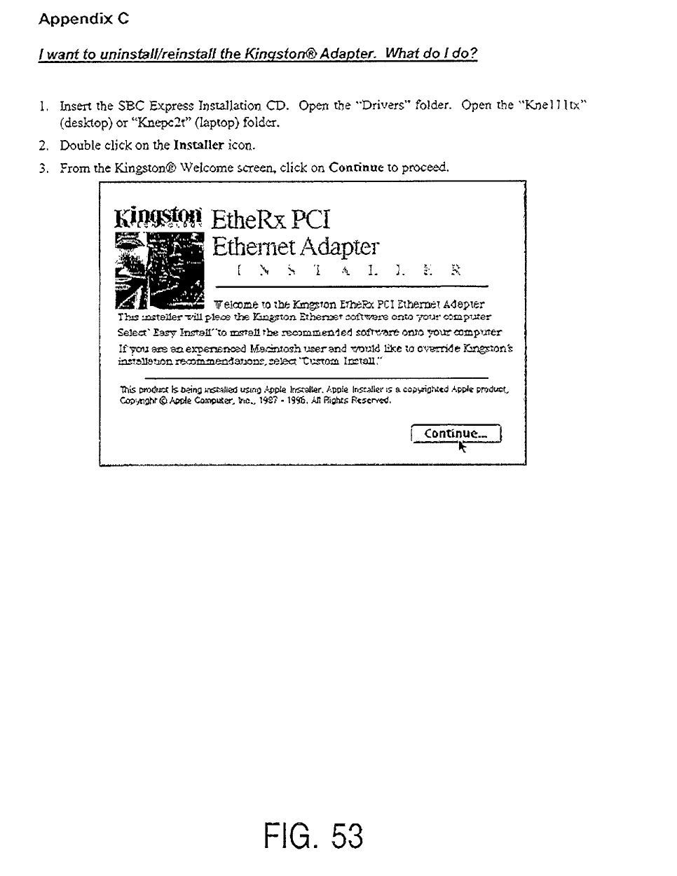

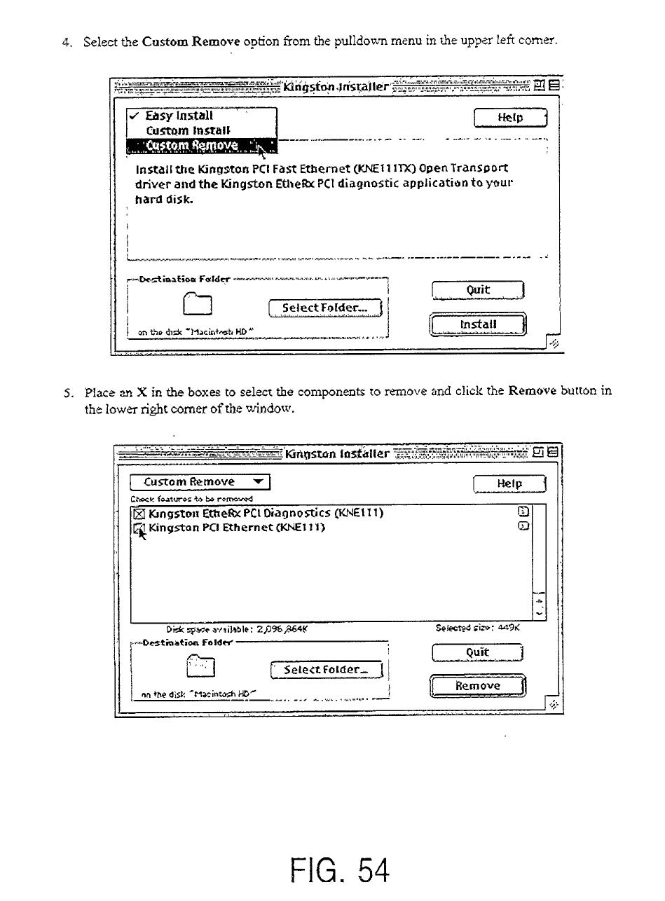

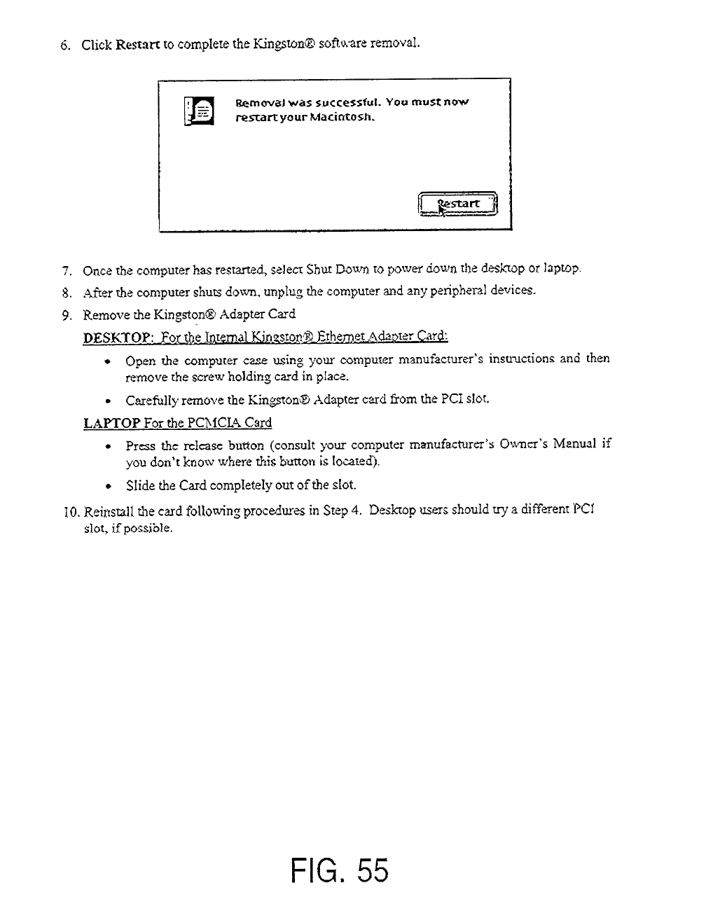

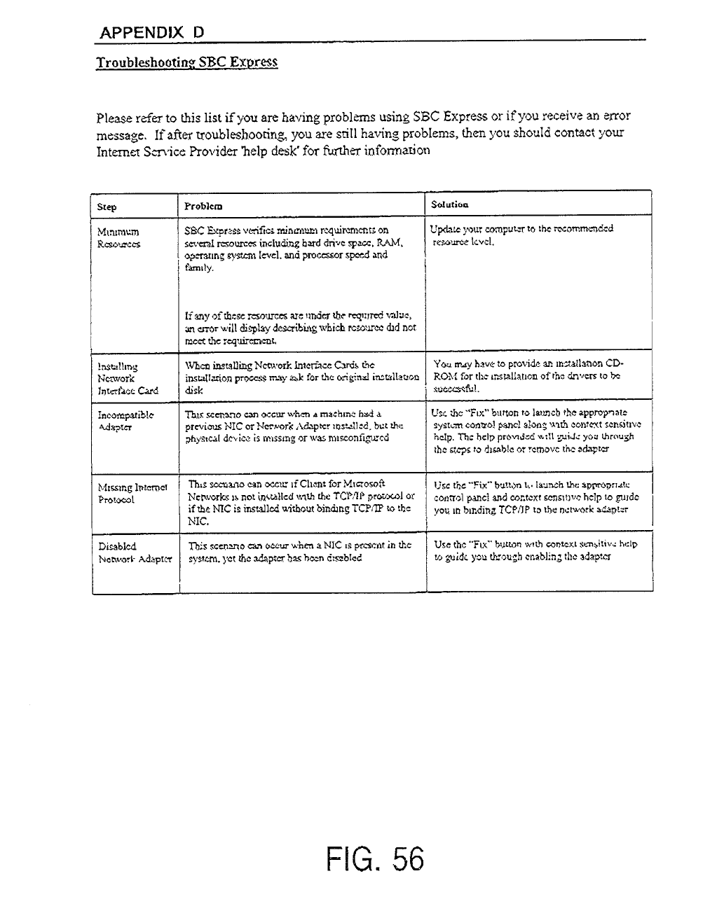

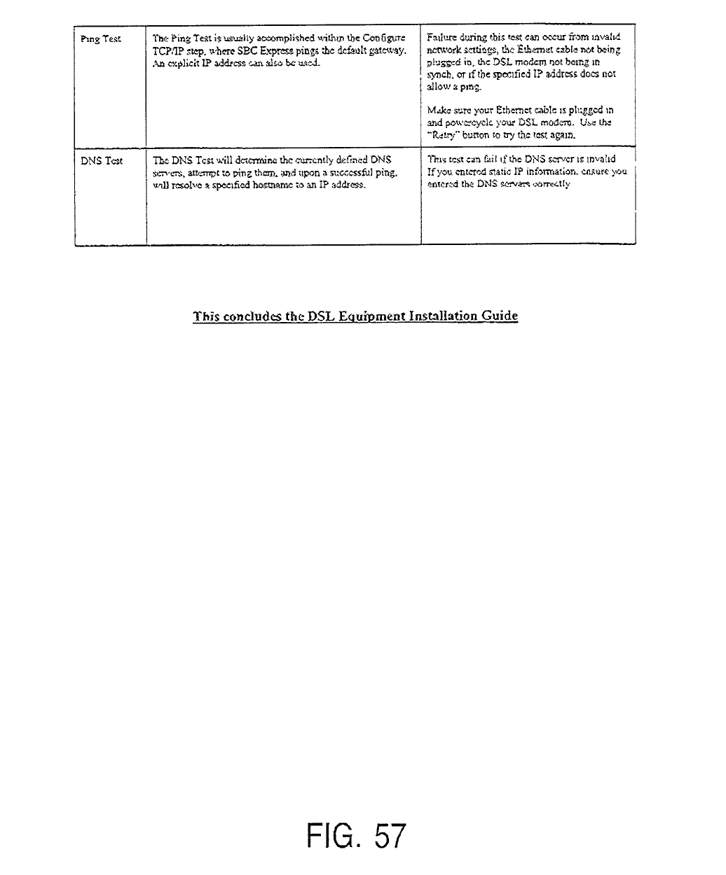

FIGS. 30 to 57 illustrate an embodiment of a unified installation manual for a second class of operating systems. The second class of operating systems consists of MACINTOSH® Operating Systems from Apple Corporation.

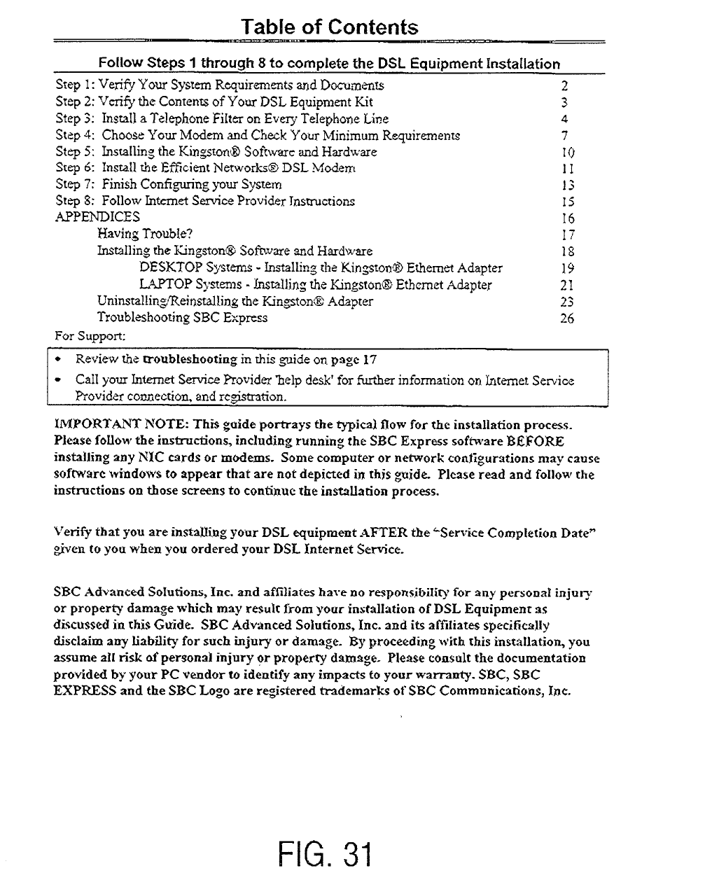

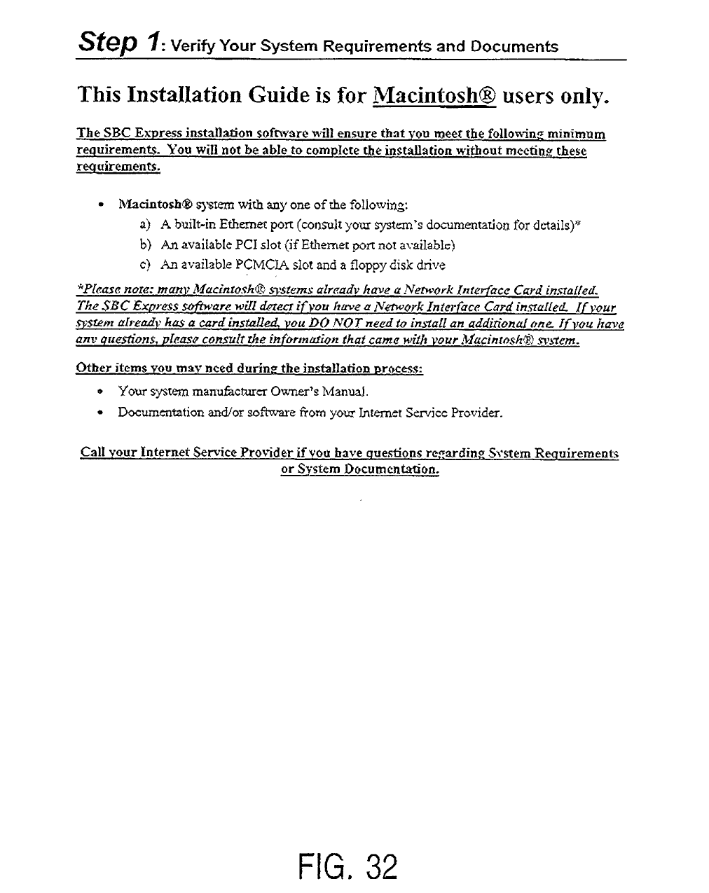

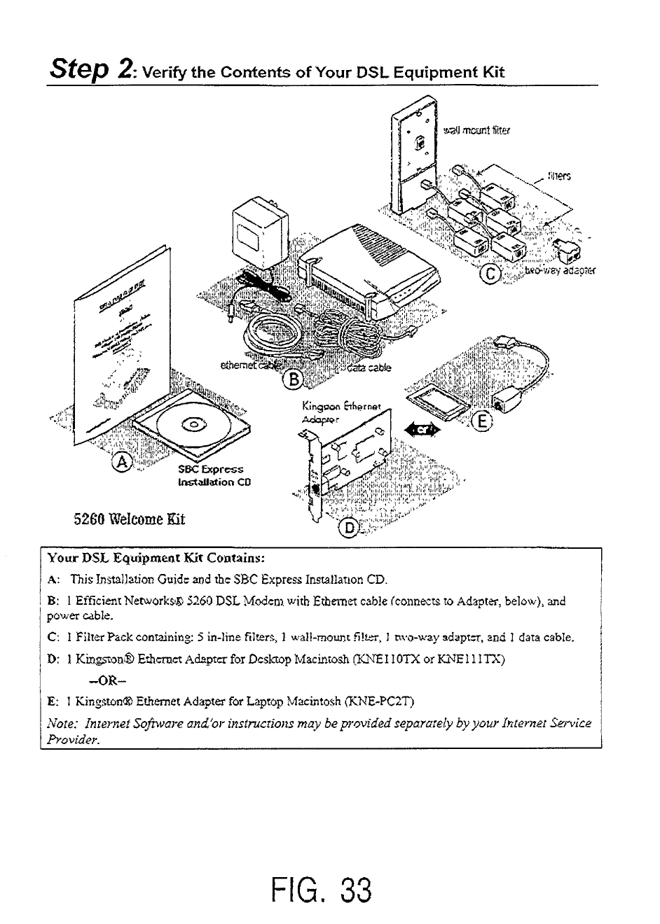

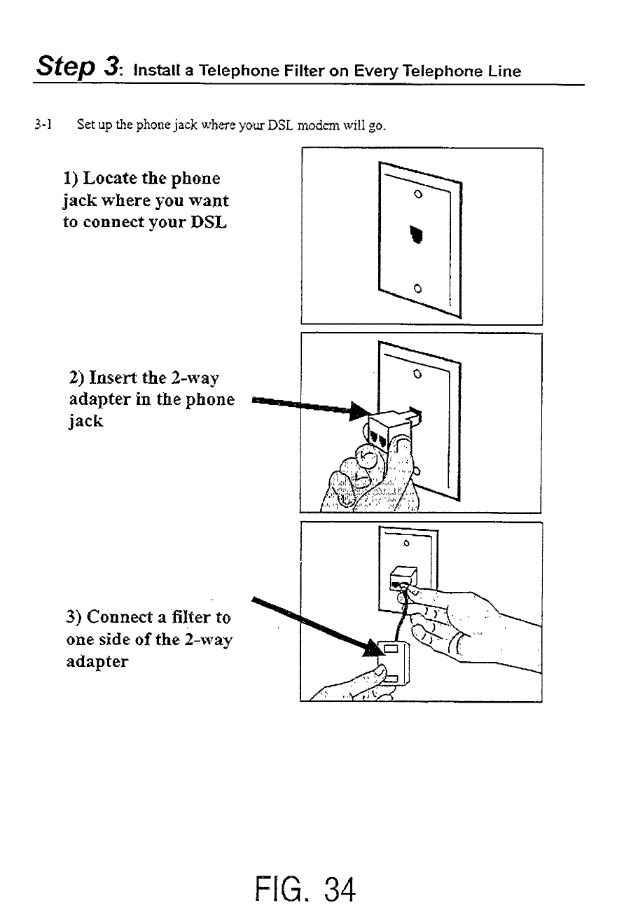

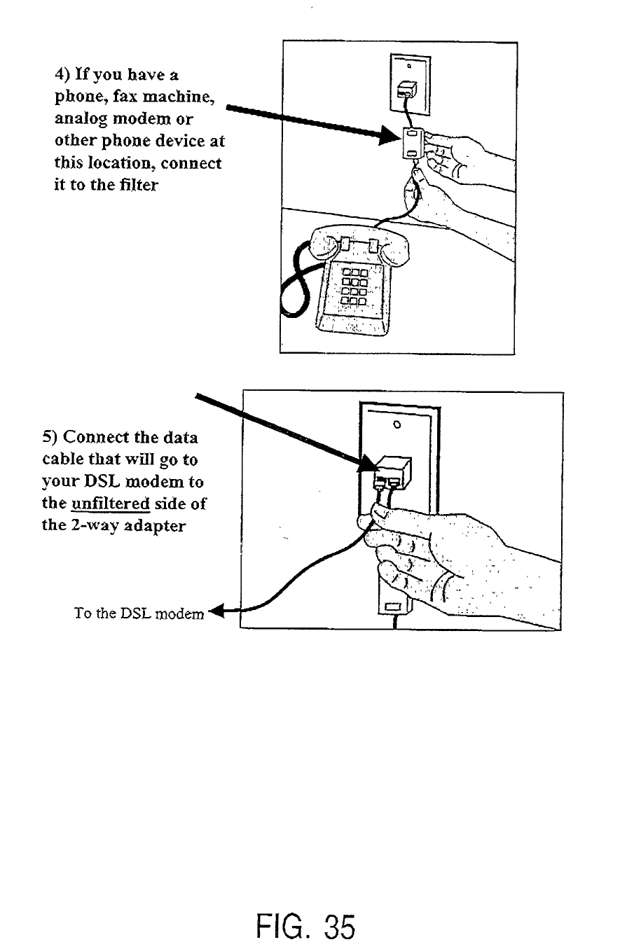

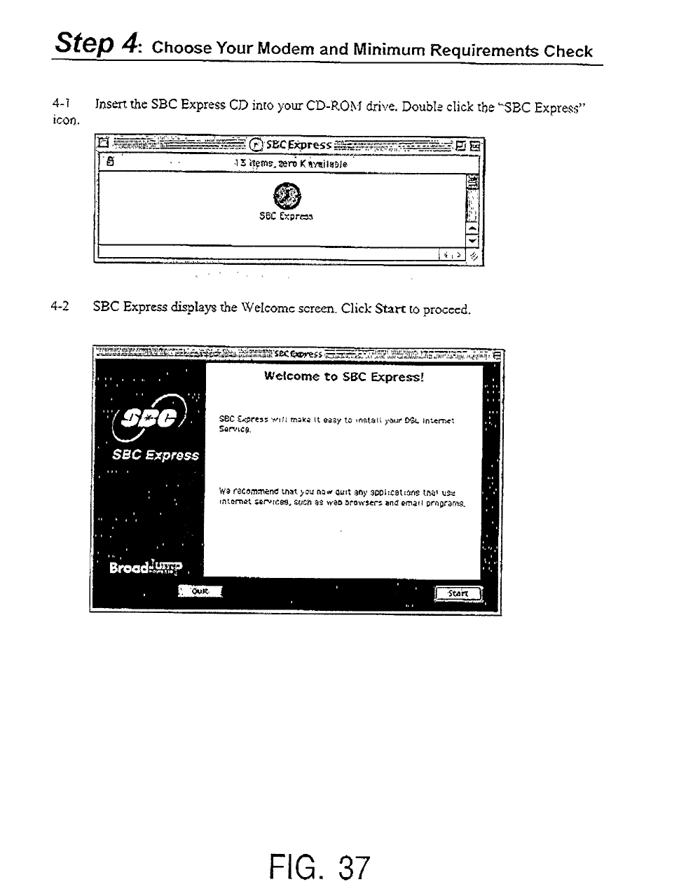

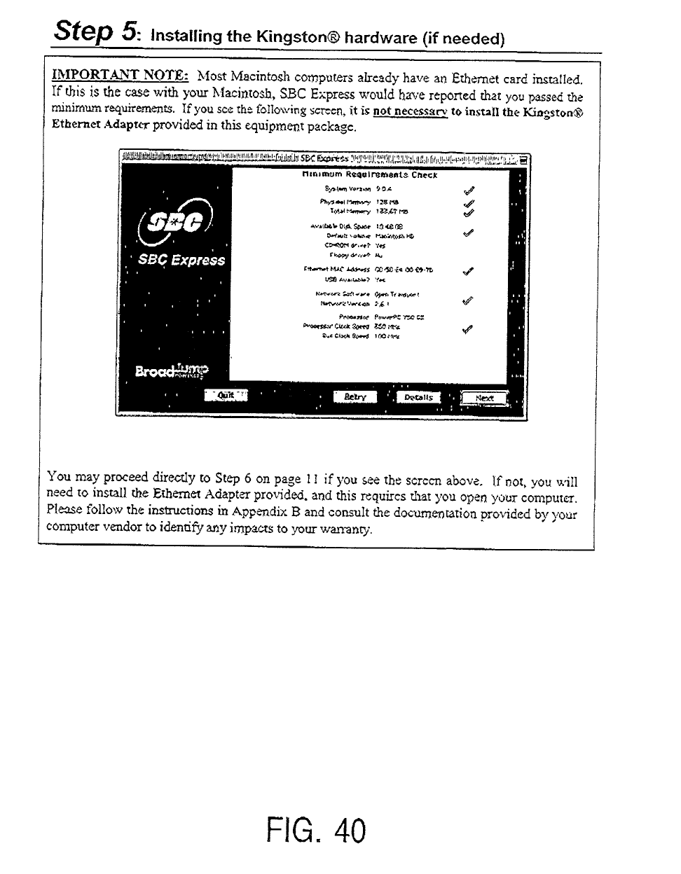

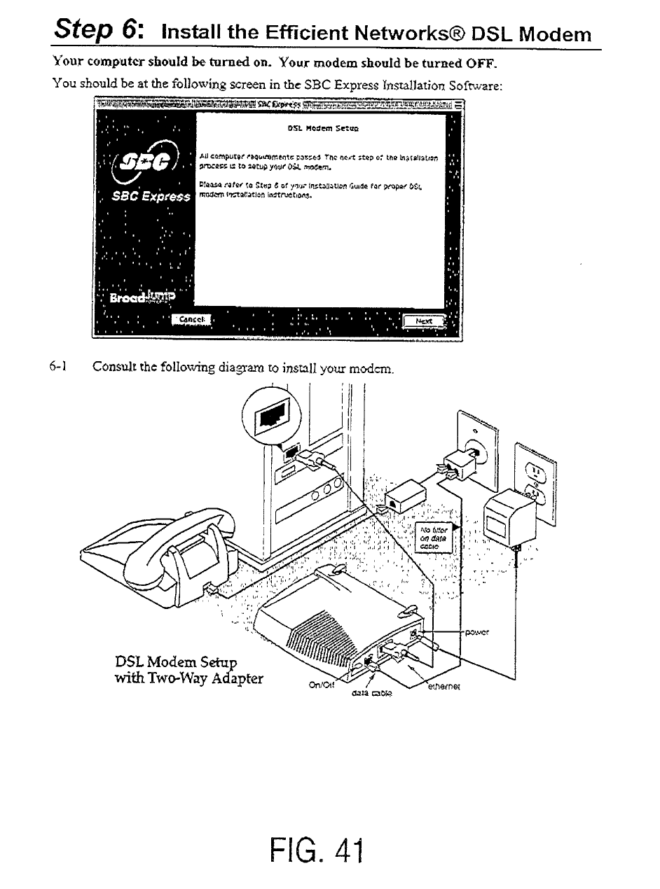

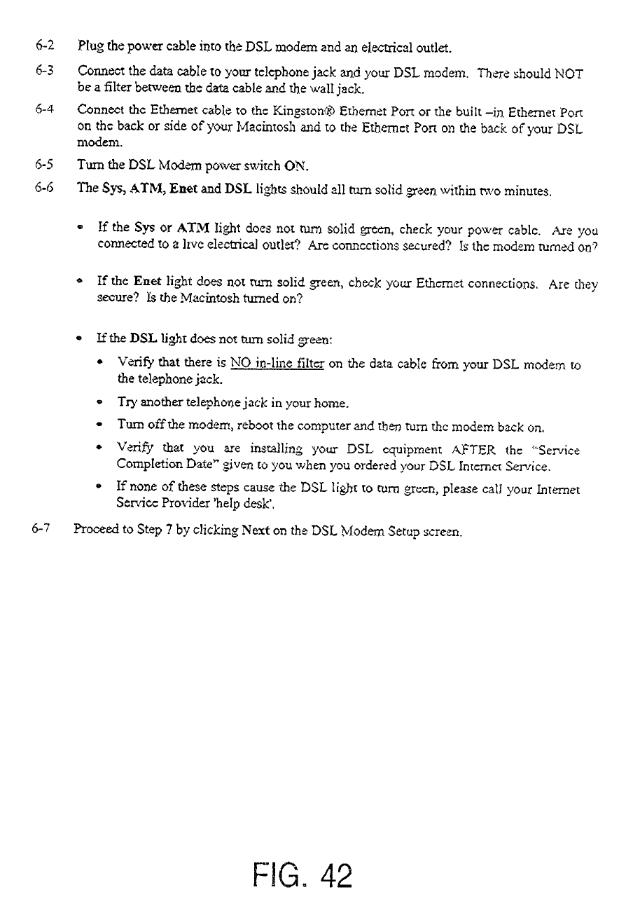

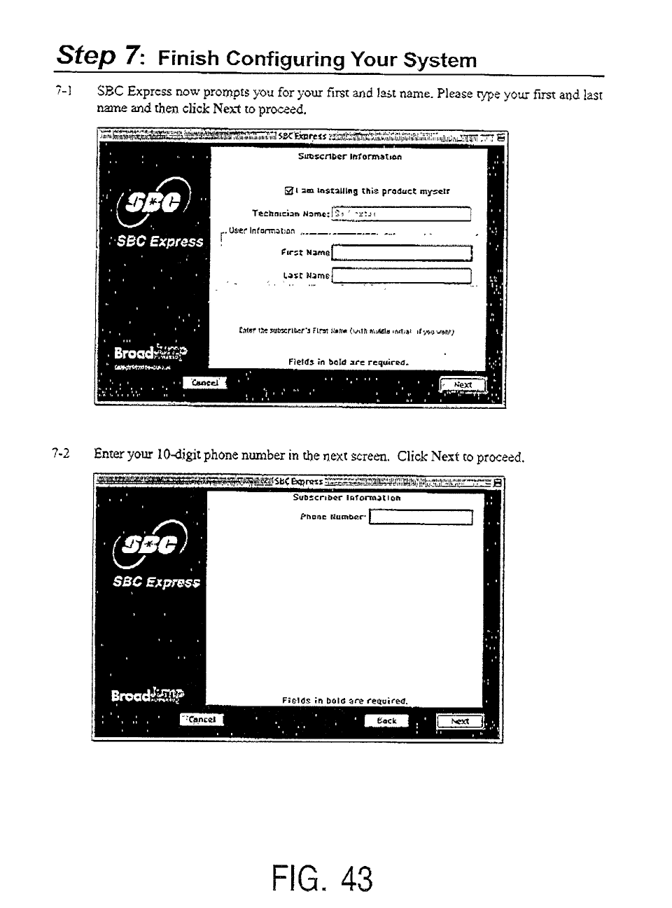

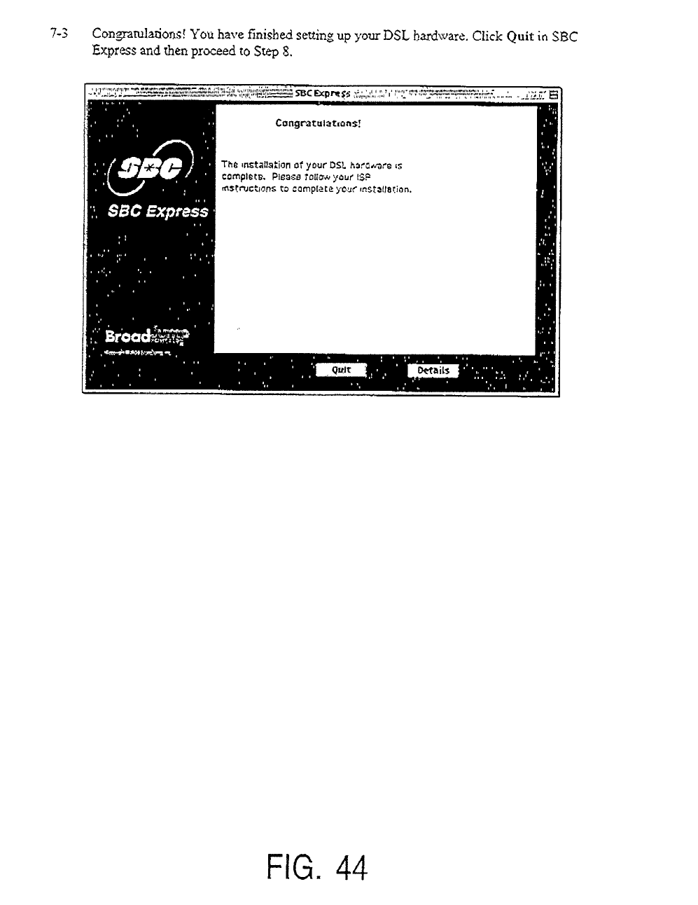

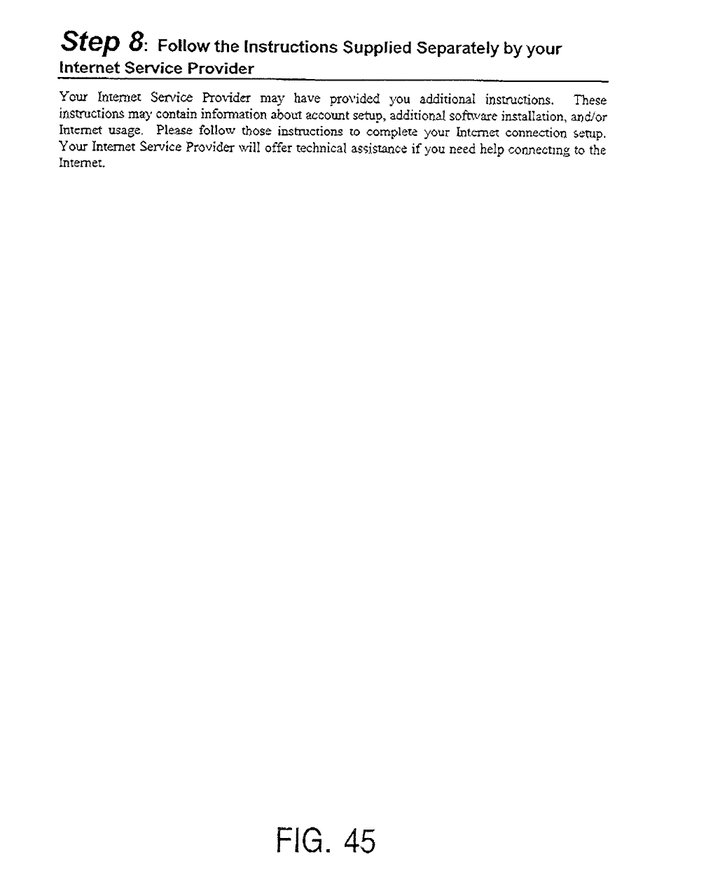

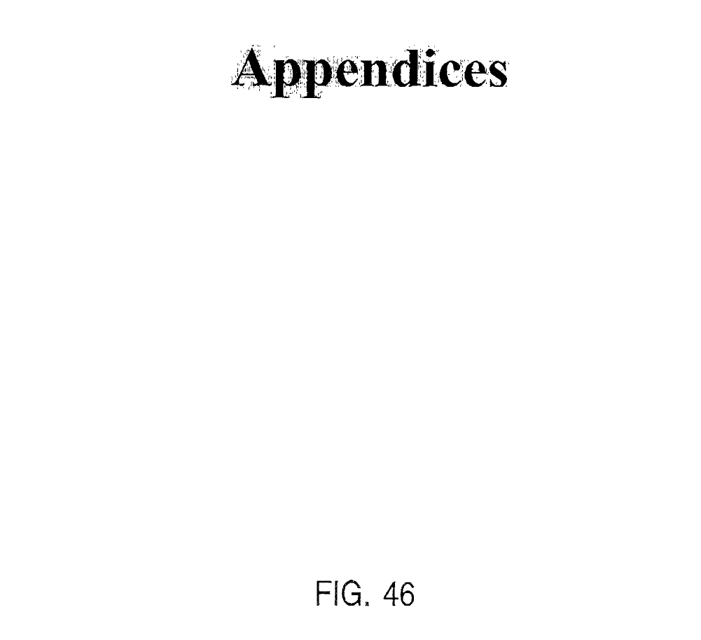

As shown in FIG. 30, the cover of the manual is clearly labeled “READ ME FIRST” and identifies the class of MACINTOSH® operating systems. FIG. 31 shows a page of the manual which provides a Table of Contents. FIG. 32 shows a page of the manual which describes a step to verify the requirements to install the components in the user's computer. FIG. 33 shows a page of the manual which describes a step to verify the contents of the kit. FIGS. 34, 35 and 36 show pages of the manual which describe a step of installing a digital subscriber line filter on every telephone line. FIGS. 37, 38 and 39 show pages of the manual which describe steps performed using connection software code. FIG. 40 shows a page of the manual which addresses whether or not to install an Ethernet network card. FIGS. 41 and 42 show pages of the manual which describe steps to install a DSL modem. FIGS. 43 and 44 show pages of the manual which describe steps performed using the connection software code to finalize configuration of the system. FIG. 45 shows a page of the manual which directs the user to install ISP-specific software code. FIGS. 46 to 57 provide appendices to supplement the installation process.

Several embodiments including preferred embodiments of a unified DSL self-installation process and kit have been described herein.

By providing a single instruction manual which describes a unified installation process, a user no longer needs to determine which manuals are pertinent and in what order to use the manuals. The single instruction manual promotes an appropriate sequence of installation steps to be followed by the user without skipping any required steps. Further, by providing the user with instructions that are correctly matched to his/her computer's operating system, errors associating with following instructions for an incorrect operating system are mitigated. Confusion and sequence errors are further mitigated by including the ISP software component with the kit. Points of contact for specific installation components may be clearly marked and associated with specific steps in the instruction manual to promote correct routing of help calls. Use of the new process has increased installation success rates from below 20% to near 95% in laboratory conditions.

It will be apparent to those skilled in the art that the disclosed invention may be modified in numerous ways and may assume many embodiments other than the preferred form specifically set out and described above. For example, instruction manuals specific to other operating systems, such as WINDOWS NT®, WINDOWS XP®, and LINUX, are also within the scope of the present disclosure. Further, instruction manuals specific to alternative DSL modems, such as those having a USB (Universal Serial Bus) interface or a PCI (Peripheral Component Interconnect) interface, are within the scope of the present disclosure.

Accordingly, it is intended by the appended claims to cover all modifications of the invention which fall within the true spirit and scope of the invention.

What is claimed is:

1. A digital subscriber line self-installation kit comprising:
a digital subscriber line modem;
at least one digital subscriber line filter;
a computer-readable medium whose contents comprise computer-readable connection software code; and
an instruction manual which describes a unified installation process for the digital subscriber line modem, the at least one digital subscriber line filter, and the computer-readable connection software code, wherein the unified installation process requires at most one operating system selection step by a user.

2. The kit of claim 1 wherein the unified installation process described within the instruction manual requires no operating system selection step by the user.

3. The kit of claim 1 further comprising a container which contains the digital subscriber line modem, the at least one digital subscriber line filter and the computer-readable medium.

4. The kit of claim 3 wherein the container contains the instruction manual.

5. The kit of claim 1 wherein the instruction manual provides a point of contact telephone number associated with the digital subscriber line modem.

6. The kit of claim 1 wherein the instruction manual provides a point of contact telephone number associated with the at least one digital subscriber line filter.

7. The kit of claim 1 wherein the instruction manual provides a point of contact telephone number associated with the computer-readable connection software code.

8. A digital subscriber line self-installation kit comprising:
a network card;
a digital subscriber line modem;
at least one digital subscriber line filter;
a computer-readable medium whose contents comprise computer-readable connection software code; and
an instruction manual which describes a unified installation process for the network card, the digital subscriber line modem, the at least one digital subscriber line filter, and the computer-readable connection software code, wherein the unified installation process requires at most one operating system selection step by a user.

9. The kit of claim 8 wherein the unified installation process described within the instruction manual requires no operating system selection step by the user.

10. The kit of claim 8 further comprising a container which contains the network card, the digital subscriber line modem, the at least one digital subscriber line filter and the computer-readable medium.

11. The kit of claim 10 wherein the container contains the instruction manual.

12. The kit of claim 8 wherein the instruction manual provides a point of contact telephone number associated with the network card.

13. The kit of claim 8 wherein the instruction manual provides a point of contact telephone number associated with the digital subscriber line modem.

14. The kit of claim 8 wherein the instruction manual provides a point of contact telephone number associated with the at least one digital subscriber line filter.

15. The kit of claim 8 wherein the instruction manual provides a point of contact telephone number associated with the computer-readable connection software code.

16. A digital subscriber line self-installation kit comprising:
a network card;
a digital subscriber line modem;
at least one digital subscriber line filter;
at least one computer-readable medium whose contents comprise computer-readable connection software code and computer-readable internet service provider specific software code; and
an instruction manual which describes a unified installation process for the network card, the digital subscriber line modem, the at least one digital subscriber line filter, the computer-readable connection software code and the computer-readable internet service provider specific software code, wherein the unified installation process requires at most one operating system selection step by a user.

17. The kit of claim 16 wherein the unified installation process described within the instruction manual requires no operating system selection step by the user.

18. The kit of claim 17 further comprising a container which contains the network card, the digital subscriber line modem, the at least one digital subscriber line filter and the at least one computer-readable medium.

19. The kit of claim 18 wherein the container contains the instruction manual.

20. The kit of claim 8 wherein the instruction manual provides a point of contact telephone number associated with the computer-readable internet service provider specific software code.
